(19) United States
(12) Patent Application Publication
(10) Pub. No.: US 2024/0179841 A1
(43) Pub. Date: May 30, 2024

(54) OPTICAL DEVICE, CAMERA, AND CIRCUIT MODULE

(71) Applicant: CANON KABUSHIKI KAISHA, Tokyo (JP)

(72) Inventors: HIDETO TAKAHASHI, Tokyo (JP); MITSUTOSHI HASEGAWA, Kanagawa (JP); SATORU HIGUCHI, Tokyo (JP); NORITAKE TSUBOI, Kanagawa (JP)

(21) Appl. No.: 18/518,146

(22) Filed: Nov. 22, 2023

(30) Foreign Application Priority Data
Nov. 28, 2022 (JP) 2022-189344

(51) Int. Cl. H05K 1/14

(52) U.S. Cl. CPC H05K 1/141; G02B 7/14; H05K 2201/09027; H05K 2201/09227; H05K 2201/10984

(57) ABSTRACT

An optical device includes a lens optical system, a first circuit board, and a second circuit board. The lens optical system includes a plurality of lenses disposed along an optical axis. The first circuit board has a first main surface extending along a direction intersecting the optical axis of the lens optical system and has a second main surface on a side of the first circuit board that is opposite from a side that the first main surface is on. The second circuit board has a third main surface extending along a direction intersecting the first main surface and has a fourth main surface on a side of the second circuit board that is opposite from a side that the third main surface is on. The first circuit board and the second circuit board are soldered to each other.

### BACKGROUND

### Field

The present disclosure relates to an optical device.

### Description of the Related Art

In a lens-interchangeable camera system, an optical device (interchangeable lens) connected to an image capturing device (camera body) includes therein a circuit board in which electronic components for realizing an auto focus system and the like are mounted on a printed wiring board. Since an optical system is disposed, an annular-shaped or an arc-shaped printed wiring board is used for the circuit board in the interchangeable lens.

As the size of the image capturing device reduces and image quality and performance of the image capturing device improves, the size of the electronic components of the interchangeable lens also reduces and performance of the interchangeable lens improves in correction of blurring and the like. The circuit board in the interchangeable lens includes a system circuit in which mainly semiconductor components such as a central processing unit (CPU) and the like are mounted and a driver system circuit such as a power supply, and the density in mounting the semiconductor components and many electronic components on the printed wiring board is increasing. In the case of a printed wiring board, the width of the printed wiring board is determined by the size of the semiconductor components such as the CPU and disposition of the electronic components. That is, the outer diameter of the lens inside the printed wiring board is restricted or the outer diameter of the interchangeable lens increases. To realize an interchangeable lens having a small size and exhibiting high performance, the density of mounting is required to be further increased. This issue is not limited to the lens-interchangeable camera system. A similar issue arises with a camera system with a fixed lens.

Japanese Patent Laid-Open No. 2003-172863 discloses an electric substrate mounting structure in which, in an interchangeable lens unit, a hard substrate perpendicular to an optical axis and a hard substrate parallel to the optical axis are connected to each other through a board-to-board connector. There is room for improvement of reliability of connection between the substrates in the technique according to Japanese Patent Laid-Open No. 2003-172863.

### SUMMARY

Accordingly, the present disclosure provides a technique that is useful in improving reliability of connection of a circuit board in an optical device.

According to an aspect of the present disclosure, an optical device includes a lens optical system that includes a plurality of lenses disposed along an optical axis, a first circuit board that has a first main surface extending along a direction intersecting the optical axis of the lens optical system and has a second main surface on a side of the first circuit board that is opposite from a side that the first main surface is on, and a second circuit board that has a third main surface extending along a direction intersecting the first main surface and has a fourth main surface on a side of the second circuit board that is opposite from a side that the third main surface is on, wherein the first circuit board and the second circuit board are soldered to each other.

Further features of the present disclosure will become apparent from the following description of exemplary embodiments with reference to the attached drawings.

### BRIEF DESCRIPTION OF THE DRAWINGS

FIGS. 1A and 1B are schematic views illustrating an optical device.

FIGS. 2A and 2B are schematic views illustrating a circuit module.

FIGS. 3A-1 to 3A-3 and 3B-1 to 3B-2 are schematic views illustrating connection electrodes of a sub-circuit board and a printed wiring board.

FIGS. 4A to 4C are schematic views illustrating the circuit module.

FIG. 5 includes FIGS. 5(a) to 5(d), which are schematic views illustrating a method for manufacturing the circuit module.

FIGS. 6A and 6B are schematic views illustrating the circuit module.

FIGS. 7A and 7B are schematic views illustrating the circuit module.

FIGS. 8A to 8C are schematic views illustrating the circuit module.

FIGS. 9A to 9C are schematic views illustrating the circuit module.

FIGS. 10A to 10C are schematic views illustrating the circuit module.

FIGS. 11A and 11B are schematic views illustrating the circuit module.

FIGS. 12A to 12F are schematic views illustrating a method for manufacturing the sub-circuit board.

FIGS. 13A and 13B are schematic views illustrating the circuit module.

FIGS. 14A and 14B are schematic views illustrating the circuit module.

### DESCRIPTION OF THE EMBODIMENTS

Hereinafter, embodiments of the present disclosure will be described with reference to the drawings. In the description and the drawings below, elements common to a plurality of the drawings are denoted by common numerals.

Accordingly, common elements are described through cross-reference of a plurality of the drawings to omit description of the elements denoted by common numerals as appropriate.

The embodiments of the present disclosure will be described in detail below with reference to the drawings.

### Optical Device

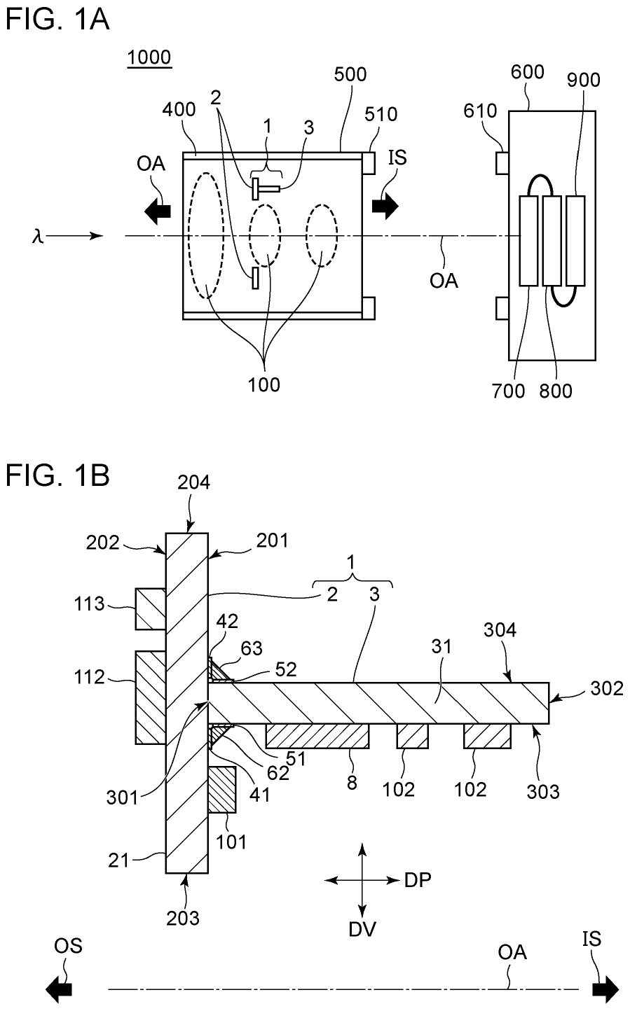

FIG. 1A is an explanatory view of an optical device 500 according to the present embodiment, illustrating a camera 1000 including the optical device 500. The camera 1000 may be referred to as a camera system. The camera 1000 includes a camera body 600. Although the optical device 500 illustrated in FIG. 1A is, for example, an interchangeable lens of a lens-interchangeable camera, the optical device 500 is a fixed lens in a camera with a fixed lens.

The optical device 500 includes a lens optical system 100, a main circuit board 2, and a sub-circuit board 3. The lens optical system 100 may include a plurality of lenses. Although the details will be described later, the main circuit board 2 and the sub-circuit board 3 are soldered to each other. The main circuit board 2 and the sub-circuit board 3 are included in a circuit module 1. The optical device 500 can further include a lens barrel 400. The circuit module 1 and the lens optical system 100 are disposed in the lens barrel 400, and the circuit module 1 is fixed to the lens barrel 400. Although at least a subset of the lenses of the lens optical system 100 can be fixed to the lens barrel 400, at least a subset of the lenses of the lens optical system 100 may be movable in the lens barrel 400. The lens optical system 100 has an optical axis OA. The plurality of lenses included in the lens optical system 100 are disposed along the optical axis OA. As illustrated in FIG. 1A, light λ from an object (photographic subject) is incident on the lens optical system 100. An object side OS and an image side IS are defined relative to the lens optical system 100. The object (photographic subject) is positioned on the object side OS of the lens optical system 100, and an image capturing device 700 is positioned on the image side of the lens optical system 100.

The camera body 600 includes the image capturing device 700 such as a complementary metal-oxide-semiconductor (CMOS) image sensor. The camera body 600 may include a processing device 800 (image processing device) that performs image processing on an image signal output from the image capturing device 700. The camera body 600 may include a display device 900 that displays an image having undergone the processing performed by the processing device 800. The display device 900 is a liquid crystal display, an electroluminescent (EL) display, or the like. The display device 900 may be an electronic view finder.

The optical device 500 includes a connection mechanism 510, and the camera body 600 includes a connection mechanism 610. The connection mechanisms 510 and 610 are also referred to as a mount. The connection mechanism 510 of the optical device 500 is connected to the connection mechanism 610 of the camera body 600. Thus, the optical device 500 and the camera body 600 are mechanically and electrically connected to each other. With this configuration, an image formed by the optical device 500 is captured by the image capturing device 700. The connection mechanisms 510 and 610 may be omitted from a camera with a fixed lens.

FIG. 1B is an explanatory view of the optical device 500 according to the present embodiment, mainly illustrating the circuit module 1.

The main circuit board 2 has a main surface 201 extending along a direction DV that intersects the optical axis OA of the lens optical system 100 and a main surface 202 on the opposite side of the main circuit board 2 from the main surface 201. The main circuit board 2 also has an end surface 203 that connects the main surface 201 and the main surface 202 to each other and an end surface 204 on the opposite side of the main circuit board 2 from the end surface 203 in the direction DV. The end surface 204 is positioned on the opposite side from the optical axis OA with respect to the end surface 203. The main circuit board 2 includes a wiring board 21 such as a printed wiring board and electronic components placed on the wiring board 21. Although a typical wiring board 21 includes a glass epoxy board serving as an insulating board and a copper layer serving as a wiring layer, the insulating board of the wiring board 21 may be a ceramic board or a resin board other than the glass epoxy board. At least one of the main surface 201 and the main surface 202 of the main circuit board 2 is a mounting surface of the wiring board 21. The electronic components placed on the wiring board 21 are, for example, surface mounted on mounting surfaces of the wiring board 21. The main circuit board 2 may include a passive component 101 placed on the main surface 201 as an electronic component placed on the wiring board 21. The main circuit board 2 may include an electronic component 112 placed on the main surface 202 as the electronic component placed on the wiring board 21. In the present example, the electronic component 112 is superposed on the sub-circuit board 3. The main circuit board 2 may include a passive component 113 placed on the main surface 202 as the electronic component placed on the wiring board 21. The passive component 113 illustrated in FIG. 1B may be a coil component such as an inductor or a transformer. When a coil component generating a magnetic field is placed on the main surface 202 on the object side OS, compared to the case where the coil component is placed on the main surface 201 on the image side IS, the magnetic field reaching the image capturing device 700 can be reduced, and noise ascribable to the magnetic field can be reduced.

The sub-circuit board 3 has a main surface 303 extending along a direction DP that intersects the main surface 201 and a main surface 304 on the opposite side of the sub-circuit board 3 from the main surface 303. The sub-circuit board 3 also has an end surface 301 that connects the main surface 303 and the main surface 304 to each other and an end surface 302 on the opposite side of the sub-circuit board 3 from the end surface 301 in the direction DP.

The end surface 302 is positioned on the opposite side from the main circuit board 2 with respect to the end surface 301. The sub-circuit board 3 includes a wiring board 31 such as a printed wiring board and electronic components placed on the wiring board 31. Although a typical wiring board 31 includes a glass epoxy board serving as an insulating board and a copper layer serving as a wiring layer, the insulating board of the wiring board 31 may be a ceramic board or a resin board other than the glass epoxy board. At least one of the main surface 303 and the main surface 304 of the sub-circuit board 3 is a mounting surface of the wiring board 31. The electronic components placed on the wiring board 31 are, for example, surface mounted on mounting surfaces of the wiring board 31. The sub-circuit board 3 may include integrated-circuit component 8 placed on the main surface 303 as the electronic components place on the wiring board 31. The sub-circuit board 3 may include a plurality of passive components 102 placed on the main surface 303 as the electronic components place on the wiring board 31. The plurality of passive components 102 may have a longitudinal direction and a transverse direction. The plurality of passive components 102 are, for example, chip components such as a chip resistor and a chip capacitor, and the longitudinal direction of a chip component is a direction in which two terminals of the chip component are arranged. An angle formed between the longitudinal direction of at least one passive component 102 out of the plurality of passive components 102 and the main surface 201 may be greater than or equal to 60 degrees. Furthermore, an angle formed between the longitudinal direction of at least one passive component 102 out of the plurality of passive components 102 and the main surface 201 may be smaller than or equal to 30 degrees. Out of the plurality of passive components 102, the number of passive components 102 having a longitudinal direction that forms an angle of greater than or equal to 60 degrees with the main surface 201 may be greater than the number of passive components 102 having a longitudinal direction that forms an angle of smaller than or equal to 30 degrees with the main surface 201.

Although the angle which the direction DV intersecting the optical axis OA forms with the optical axis OA is, for example, 90 degrees, it is sufficient that this angle be greater than 0 degrees, and this angle is preferably greater than or equal to 30 degrees, and more preferably greater than or equal to 45 degrees. The angle in which the direction DV intersecting the optical axis OA forms with the optical axis OA is still more preferably greater than or equal to 60 degrees, and particularly preferably greater than or equal to 75 degrees. Although the angle which the direction DP intersecting the main surface 201 forms with the main surface 201 is, for example, 90 degrees, it is sufficient that this angle be greater than 0 degrees, and this angle is preferably greater than or equal to 30 degrees, and more preferably greater than or equal to 45 degrees. The angle which the direction DP intersecting the main surface 201 forms with the main surface 201 is still more preferably greater than or equal to 60 degrees, and particularly preferably greater than or equal to 75 degrees. Although the angle which the direction DV forms with the direction DP is, for example, 90 degrees, it is sufficient that this angle be greater than 0 degrees, and this angle is preferably greater than or equal to 30 degrees, more preferably greater than or equal to 45 degrees, still more preferably greater than or equal to 60 degrees, and particularly preferably greater than or equal to 75 degrees.

In the present example, in the direction DP extending along the optical axis OA, the sub-circuit board 3 is disposed on the image side IS of the lens optical system 100 relative to the main circuit board 2. In this way, the main circuit board 2 can shield the sub-circuit board 3 from the light λ illustrated in FIG. 1A. Accordingly, generation of stray light due to disposition of the sub-circuit board 3 can be suppressed. When influence of the stray light is small or other countermeasures against the stray light are provided, the sub-circuit board 3 may be disposed on the object side OS of the lens optical system 100 relative to the main circuit board 2 in the direction DP extending along the optical axis OA. In the present example, the main surface 303 is positioned between the main surface 304 and the optical axis OA. With this configuration, the electronic components (particularly, the integrated-circuit component 8) placed on the main surface 303 can face a wide space on the optical axis OA side, and accordingly, the heat dissipation effect of the electronic components placed on the main surface 303 can be improved. When influence of heat generation of the electronic components is small or other heat dissipating measures are provided, the main surface 304 may be positioned between the main surface 303 and the optical axis OA.

Soldering of the main circuit board 2 and the sub-circuit board 3 is described.

The circuit module 1 may include solder 62 with which the main circuit board 2 and the sub-circuit board 3 are soldered to each other. The main circuit board 2 includes a connection electrode group 41 at the main surface 201, and the sub-circuit board 3 includes a connection electrode group 51 at the main surface 303. Referring to FIG. 1B, a section of one of electrodes of the connection electrode group 41 and a section of one of electrodes of the connection electrode group 51 are illustrated. The connection electrode group 41 and the connection electrode group 51 are soldered to each other. In more detail, each of a plurality of connection electrodes included in the connection electrode group 41 and a corresponding one of a plurality of connection electrodes included in the connection electrode group 51 are soldered to each other with the solder 62. A joint region that includes at least one of an alloy and a chemical compound is formed between the solder 62 and the connection electrode group 41. A joint region that includes at least one of an alloy and a chemical compound is formed between the solder 62 and the connection electrode group 51. The alloy or the chemical compound included in this joint region is an alloy or a chemical compound of metal elements included in the connection electrodes and metal elements included in the solder.

The circuit module 1 may also include solder 63 with which the main circuit board 2 and the sub-circuit board 3 are soldered to each other. The main circuit board 2 includes a connection electrode group 42 at the main surface 201, and the sub-circuit board 3 includes a connection electrode group 52 at the main surface 303. Referring to FIG. 1B, a section of one of electrodes of the connection electrode group 42 and a section of one of electrodes of the connection electrode group 52 are illustrated. The connection electrode group 42 and the connection electrode group 52 are soldered to each other. In more detail, each of a plurality of connection electrodes included in the connection electrode group 42 and a corresponding one of a plurality of connection electrodes included in the connection electrode group 52 are soldered to each other with the solder 63. A joint region that includes at least one of an alloy and a chemical compound is formed between the solder 63 and the connection electrode group 42. A joint region that includes at least one of an alloy and a chemical compound is formed between the solder 63 and the connection electrode group 52. The alloy or the chemical compound included in this joint region is an alloy or a chemical compound of metal elements included in the connection electrodes and metal elements included in the solder.

Here, although an example in which the connection electrode group 41 and the connection electrode group 51 are joined to each other with the solder 62 and the connection electrode group 42 and the connection electrode group 52 are joined to each other with the solder 63 is described, this is not limiting. For example, one combination out of a combination of the connection electrode group 41, the connection electrode group 51, and the solder 62 and a combination of the connection electrode group 42, the connection electrode group 52, and the solder 63 may be omitted. That is, the sub-circuit board 3 can be soldered only on a single surface side out of the main surface 303 side and the main surface 304 side. Alternatively, as a substitute for the connection electrode group 51 or the connection electrode group 52, a connection electrode group (not illustrated) can be provided on the end surface 301 of the sub-circuit board 3 (wiring board 31). Solder (not illustrated) as a substitute for the solder 62 or the solder 63 can be disposed between the connection electrode group (not illustrated) provided on the end surface 301 and the connection electrode group provided on the main surface 201. The connection electrode group (not illustrated) provided on the end surface 301 and the connection electrode group provided on the main surface 201 can be soldered to each other with this solder. However, when the sub-circuit board 3 is soldered from both the main surface 303 side and the main surface 304 side, the sub-circuit board 3 can be firmly supported by the main circuit board 2. In particular, the circuit module 1 can become robust against forces exerted on the sub-circuit board 3 in the direction DV, especially, a force that is centered at the end surface 301 as the rotation center and that is exerted on the sub-circuit board 3.

The main circuit board 2 and the sub-circuit board 3 can be disposed such that the main surface 303 or the main surface 304 of the sub-circuit board 3 faces the end surface 203 or the end surface 204 of the main circuit board 2. In this case, as a substitute for the connection electrode group 41 or the connection electrode group 42, a connection electrode group (not illustrated) can be provided on the main surface 303 or the main surface 304. When the main surface 303 or the main surface 304 of the sub-circuit board 3 faces the end surface 203 of the main circuit board 2, it is sufficient that a connection electrode group as a substitute for the connection electrode group 51 or the connection electrode group 52 be provided on the end surface 203, in a region of the main surface 201 near the end surface 203, or in a region of the main surface 202 near the end surface 203. When the main surface 303 or the main surface 304 of the sub-circuit board 3 faces the end surface 204 of the main circuit board 2, it is sufficient that a connection electrode group as a substitute for the connection electrode group 51 or the connection electrode group 52 be provided on the end surface 204, in a region of the main surface 201 near the end surface 204, or in a region of the main surface 202 near the end surface 204.

Hereinafter, more specific embodiments are described.

### First Embodiment

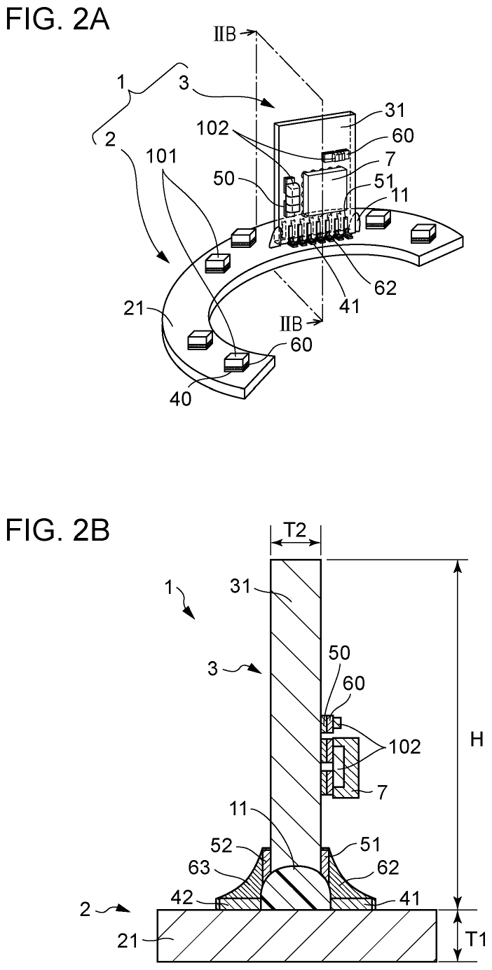

FIGS. 2A and 2B are explanatory views of the circuit module 1 in an interchangeable lens. FIG. 2A is a perspective view illustrating a first embodiment, and FIG. 2B is a sectional view illustrating the first embodiment taken along plane JIB-JIB of FIG. 2A. The lens optical system 100 including a plurality of lenses, the circuit module 1 including the main circuit board 2 and the sub-circuit board 3, a lens holding mechanism (not illustrated), and so forth are disposed in the lens barrel 400.

Since the lens optical system 100 is disposed in the center in a direction perpendicular to the optical axis OA, the end surface 203 of the main circuit board 2 illustrated in FIG. 1B has an arc shape or an annular shape. In the present example, the end surface 203 has an arc shape. When the end surface 203 has an arc shape or an annular shape, it can be said that the end surface 203 extends along an arc. Since the circuit module 1 is disposed in the cylinder-shaped lens barrel 400, the end surface 204 illustrated in FIG. 1B has an arc shape or an annular shape. In the present example, the end surface 204 has an arc shape.

When the end surface 204 has an arc shape or an annular shape, it can be said that the end surface 204 extends along an arc. The end surface 203 extending along the arc is positioned between the end surface 204 extending along the arc and the center of the arc along which the end surface 204 extends. The main circuit board 2 of the present example has the end surface 203 and the end surface 204 having respective shapes along the arcs and has an arc shape having ends in a direction extending along the arc. However, the main circuit board 2 may have the end surface 203 and the end surface 204 having respective shapes along the arcs and may have an annular shape having no end in the direction extending along the arc. The radius of the arc along which the arc-shaped end surface 204 extends, that is, the radius of curvature of the end surface 204 is greater than the radius of the arc along which the arc-shaped end surface 203 extends, that is, the radius of curvature of the end surface 203. In neither the arc-shaped main circuit board 2 nor the annular main circuit board 2, the main circuit board 2 exists in the center of the arc. The main surface 303 and the main surface 304 of the sub-circuit board 3 are disposed along the direction DP parallel to the optical axis OA. The outline of the sub-circuit board 3 is a quadrilateral, and one side of the quadrilateral is the end surface 301 illustrated in FIG. 1B, and another side of the quadrilateral facing the one side corresponding to the end surface 301 is the end surface 302 illustrated in FIG. 1B.

A thickness T1 of the main circuit board 2 corresponds to the distance between the main surface 201 and the main surface 202 of the main circuit board 2 illustrated in FIG. 1B. A thickness T2 of the sub-circuit board 3 corresponds to the distance between the main surface 303 and the main surface 304 of the sub-circuit board 3 illustrated in FIG. 1B. The thickness T2 of the sub-circuit board 3 may be the same as the thickness T1 of the main circuit board 2 (T2=T1) or different from the thickness T1. The thickness T2 of the sub-circuit board 3 may be smaller than the thickness T1 of the main circuit board 2 (T2<T1).

Regarding the main circuit board 2 and the sub-circuit board 3, the connection electrode groups 41 and 42 formed on the main circuit board 2 are connected to the connection electrode groups 51 and 52 formed on the sub-circuit board 3 through the solder 62. At least system circuitry required for controlling an auto focus and so forth and a power supply circuit and so forth for drive are required for the circuit module 1 in the interchangeable lens. The sub-circuit board 3 is disposed so as to be perpendicular to the main circuit board 2 and electrically and mechanically connected to the main circuit board 2 through the solder 62. The system circuitry required for controlling the auto focus and so forth and the power supply circuit and so forth for the drive are disposed in the main circuit board 2 and the sub-circuit board 3 in a distributed manner. To allow these to interface with each other, the connection electrode groups 41 and 42 are connected to the connection electrode groups 51 and 52 formed on the sub-circuit board 3 through the solder 62. The electronic components required for the circuit module 1 are connected to connection electrodes 40 on the main circuit board 2 and lands 50 on the sub-circuit board 3 side through solder 60.

As an example, there is a case in which, as the system circuitry, integrated-circuit component 7 such as a central processing unit (CPU) or an application-specific integrated circuit (ASIC) and other electronic components (not illustrated) including an electronic components 102 are disposed on the sub-circuit board 3. In this case, a power supply IC, other semiconductor components, and electronic components 101 such as chip components of the driver circuit system are disposed on the main circuit board 2.

The distance between the integrated-circuit component 7 included in the sub-circuit board 3 and the main surface 201 can be smaller than half a height H of the sub-circuit board 3 with reference to the main surface 201. With this, the center of gravity of the sub-circuit board 3 can be set to be close to the main circuit board 2, and accordingly, the stability of the sub-circuit board 3 during the manufacture and in use can be improved.

Internal layer wiring (not illustrated) of the wiring board 21 of the main circuit board 2, internal layer wiring (not illustrated) of the wiring board 31 of the sub-circuit board 3, the connection electrodes 40, the connection electrode groups 41, 42, 51, and 52, and so forth are appropriately designed.

When the electronic components required for the system circuitry and the driver circuit system are disposed on the sub-circuit board 3 in a distributed manner, or one of the system circuitry and the driver circuit system is disposed on the sub-circuit board 3, the total number of the electronic components 101 to be disposed on the main circuit board 2 side can be reduced. The difference between the outer diameter and the inner diameter of the main circuit board 2 can be reduced, and accordingly, the inner diameter can be increased. Thus, the outer diameter of the lens can be increased, the length of the lens unit can be reduced, and the size can be reduced.

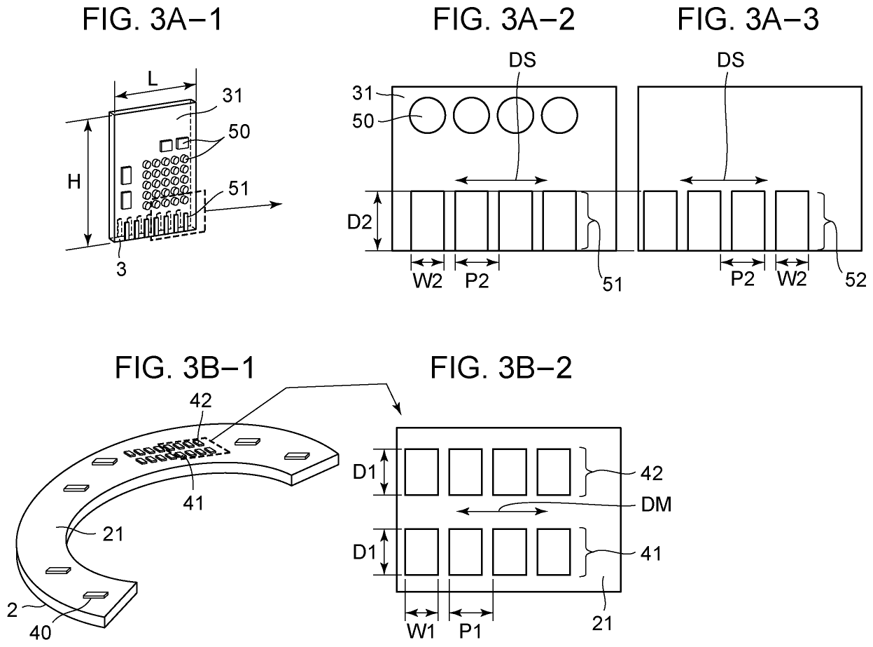

FIGS. 3A-1 to 3B-2 are schematic views illustrating an embodiment of the connection electrodes of the main-circuit board 2 and the sub-circuit board 3. FIGS. 3A-1 is a perspective view of the wiring board 31 being a printed wiring board of the sub-circuit board 3. FIG. 3A-2 is a plan view illustrating a subset (in a frame of FIG. 3A-1) of the connection electrode group 51 of the wiring board 31 illustrated in FIG. 3A-1. FIG. 3A-3 is a plan view illustrating a subset of the connection electrode group 52 of the wiring board 31. FIG. 3A-3 illustrates the connection electrode group 52 such that the connection electrode group 52 is transparently seen from a position (for example, the optical axis OA side) where the wiring board 31 is seen as illustrated in FIG. 3A-2. FIGS. 3B-1 is a perspective view of the wiring board 21 being a printed wiring board of the main circuit board 2. FIG. 3B-2 is a plan view illustrating subsets (in a frame of FIG. 3B-1) of the connection electrode groups 41 and 42 of the wiring board 21 illustrated in FIG. 3B-1.

The connection electrodes of the main circuit board 2 and the connection electrodes of the sub-circuit board 3 of the circuit module 1 in the interchangeable lens according to the present disclosure are described below.

The integrated-circuit component 7 that is a semiconductor component and other electronic components (not illustrated) including the electronic components 102 are disposed on the sub-circuit board 3. Connection electrodes (not illustrated) of the integrated-circuit component 7 and the electronic components 102 are electrically connected to connection electrodes 50 through the solder 60. Other semiconductor components, power supply components, and the electronic components 101 such as chip components are disposed on the main circuit board 2. The electrodes (not illustrated) of the other semiconductor components, the power supply components, and the electronic components 101 such as chip components are electrically connected to the connection electrodes 40 through the solder 60.

The sub-circuit board 3 may be disposed so as to be perpendicular to the main circuit board 2. In the main circuit board 2, a plurality of connection electrode groups 41 and 42 arranged on the wiring board 21 are provided at positions corresponding to the connection electrode groups 51 and 52 on both the surface of the sub-circuit board 3. Regarding the main circuit board 2 and the sub-circuit board 3, the connection electrode groups 41 and 42 formed on the main circuit board 2 are electrically and mechanically connected to the connection electrode groups 51 and 52 formed on the sub-circuit board 3 through the solder 62.

The wiring board 21 of the main circuit board 2 includes the connection electrode group 41 in which a plurality of connection electrodes is arranged on the main surface 201. The wiring board 21 of the main circuit board 2 also includes the connection electrode group 42 in which a plurality of connection electrodes is arranged on the main surface 202. In each of the connection electrode groups 41 and 42, a direction in which the plurality of connection electrodes is arranged is defined as an arrangement direction DM. The arrangement direction DM in which the plurality of connection electrodes is arranged in the connection electrode group 41 may be a direction extending along the main surface 303. The arrangement direction DM in which the plurality of connection electrodes is arranged in the connection electrode group 42 may be a direction extending along the main surface 304. The direction in which the plurality of connection electrodes is arranged in the connection electrode group 41 and the direction in which the plurality of connection electrodes is arranged in the connection electrode group 42 may intersect each other or may be parallel to each other. Herein, the direction in which the plurality of connection electrodes is arranged in the connection electrode group 41 and the direction in which the plurality of connection electrodes is arranged in the connection electrode group 42 are defined as the common arrangement direction DM.

The wiring board 31 of the sub-circuit board 3 includes the connection electrode group 51 in which a plurality of connection electrodes is arranged on the main surface 303. The wiring board 31 of the sub-circuit board 3 also includes the connection electrode group 52 in which a plurality of connection electrodes is arranged on the main surface 304. In each of the connection electrode groups 51 and 52, a direction in which the plurality of connection electrodes is arranged is defined as an arrangement direction DS. The arrangement direction DS in which the plurality of connection electrodes is arranged in the connection electrode group 51 may be a direction extending along the main surface 201. The arrangement direction DS in which the plurality of connection electrodes is arranged in the connection electrode group 52 may be a direction extending along the main surface 202. The direction in which the plurality of connection electrodes is arranged in the connection electrode group 51 and the direction in which the plurality of connection electrodes is arranged in the connection electrode group 52 may intersect each other or may be parallel to each other. Herein, the direction in which the plurality of connection electrodes is arranged in the connection electrode group 51 and the direction in which the plurality of connection electrodes is arranged in the connection electrode group 52 are defined as the common arrangement direction DS. The arrangement direction DS is a direction extending along the main surface 201. The arrangement direction DS is a direction extending along the main surface 303 and/or the main surface 304.

The arrangement direction DM being a direction in which the plurality of connection electrodes is arranged in each of the connection electrode groups 41 and 42 and the arrangement direction DS in which the plurality of connection electrodes are arranged in the connection electrode groups 51 and 52 may intersect each other or may be parallel to each other.

A pitch P1 of two electrodes adjacent to each other included in the connection electrode group 41 included in the main circuit board 2 can be smaller than the thickness T1 of the wiring board 21 of the main circuit board 2. A pitch P1 of two electrodes adjacent to each other included in the connection electrode group 42 included in the main circuit board 2 can be smaller than the thickness T1 of the wiring board 21 of the main circuit board 2. A pitch P2 of two electrodes adjacent to each other included in the connection electrode group 51 included in the sub-circuit board 3 can be smaller than the thickness T2 of the wiring board 31 of the sub-circuit board 3. The pitch P2 of two electrodes adjacent to each other included in the connection electrode group 52 included in the sub-circuit board 3 can be smaller than the thickness T2 of the wiring board 31 of the sub-circuit board 3.

The sum of lengths W2 of the plurality of electrodes of the connection electrode group 51 in the arrangement direction DS in which the plurality of electrodes included in the connection electrode group 51 are arranged can be greater than or equal to half a length L of the sub-circuit board 3 (wiring board 31) in the arrangement direction DS. For example, when the number of electrodes included in the connection electrode group 51 is M (for example, 7), the following relationship is preferably satisfied: M×W2≥L/2. The sum of lengths W2 of the plurality of electrodes of the connection electrode group 52 in the arrangement direction DS in which the plurality of electrodes included in the connection electrode group 52 are arranged is preferably greater than or equal to half the length L of the sub-circuit board 3 (wiring board 31) in the arrangement direction DS. For example, when the number of electrodes included in the connection electrode group 52 is N (for example, 7), the following relationship is preferably satisfied: N×W2≥L/2. The sum of lengths W2 of the plurality of electrodes of the connection electrode groups 51 and 52 in the arrangement direction DS in which the plurality of electrodes included in the connection electrode group 51 and the connection electrode group 52 are arranged is preferably greater than or equal to the length L of the sub-circuit board 3 (wiring board 31) in the arrangement direction DS. For example, when the number of electrodes included in the connection electrode groups 51 and 52 is M+N (for example, 14), the following relationship is preferably satisfied: (M+N)×W2≥L. Here, in the above description, it is assumed that the widths of all the connection electrodes (the length of the sub-circuit board 3 (wiring board 31) in the arrangement direction DS) is uniform. However, when the widths of the connection electrodes are not uniform, it is sufficient to sum up the widths of all the connection electrodes to be calculated.

The connection electrodes 40, 50, 41, 42, 51, and 52 are electrodes formed of electrically conductive metal, for example, copper and serve as, for example, signal electrodes, power supply electrodes, ground electrodes, or dummy electrodes. The wiring board 21 and the wiring board 31 of the main circuit board 2 and the sub-circuit board 3 are rigid boards formed of an insulating material such as epoxy resin containing fiberglass.

Solder resist films (not illustrated) may be provided on the wiring boards 21 and 31. In so doing, openings are formed at positions corresponding to the connection electrodes 40, 41, 42, 50, 51, and 52 in the solder resist films. The thickness T2, the width L, and the height H of the wiring board 31 are determined in consideration of an increase in density of the components to be mounted, ensuring or the like of the mounting area, prevention of mechanical interference between the lens barrel 400 and the lens optical system, and the width of the main circuit board 2 in a direction perpendicular to the optical axis OA. The thickness of the wiring board 31 is preferably smaller than or equal to 1 mm, and the thickness of the sub-circuit board 3 is preferably smaller than or equal to about 10 mm. The width L of the sub-circuit board 3 is preferably greater than or equal to about 10 mm. The height H of the sub-circuit board 3 is preferably greater than or equal to about 10 mm and smaller than or equal to about 50 mm. The thickness T2 can be as small as possible to increase the area of components that can be mounted on the main circuit board 2. However, when the thickness T2 is excessively small, the likelihood of the sub-circuit board 3 itself being deformed increases, and the sub-circuit board 3 cannot stand by itself due to the weight of the electronic components placed thereon. Accordingly, the thickness T2 is preferably greater than or equal to 0.2 mm.

The solder 62 is formed by becoming wet and being spread over upper and side surfaces of the connection electrode groups 41, 42, 51, and 52.

The sum of solder connecting lengths, in a direction in which the connection electrode groups 51 and 52 are arranged, of the solder 62 to which the connection electrode groups 51 and 52 and the connection electrode groups 41 and 42 are connected near the main circuit board 2 is greater than or equal to the length L of the sub-circuit board 3. This can improve reliability of connection between the main circuit board 2 and the sub-circuit board 3. The minimum pitch P1 of the connection electrode groups 41 and 42, the minimum pitch P2 of the connection electrode groups 51 and 52, and the amount of the solder 62 are appropriately designed so as not to allow shorting due to contact between pieces of the solder 62 in a state in which the solder 62 has been formed.

A subset of the connection electrode groups 41, 42, 51, and 52 is connected to ground lines of the sub-circuit board 3 and the main circuit board 2. Since a larger current than the current of the signal lines or the like flows through the ground lines, the ground lines are required to be lines having lower resistance. In order that the connection electrode groups 41, 42, 51, and 52 at positions connected to the ground lines of the sub-circuit board 3 and the main circuit board 2 correspond to a larger current, the width of the electrodes connected to the ground lines may be increased compared to the width of the electrodes to which the signal lines are connected. Although the width and the thickness of the connection electrode groups 41, 42, 51, and 52 are determined in consideration of ground lines, signal lines, use of the electronic components to be connected, the thickness is preferably greater than or equal to 0.01 mm and smaller than or equal to 2 mm. When the increase in density of the lines is considered, the width of the connection electrode groups 41, 42, 51, and 52 is more preferably smaller than or equal to 0.5 mm.

### Second Embodiment

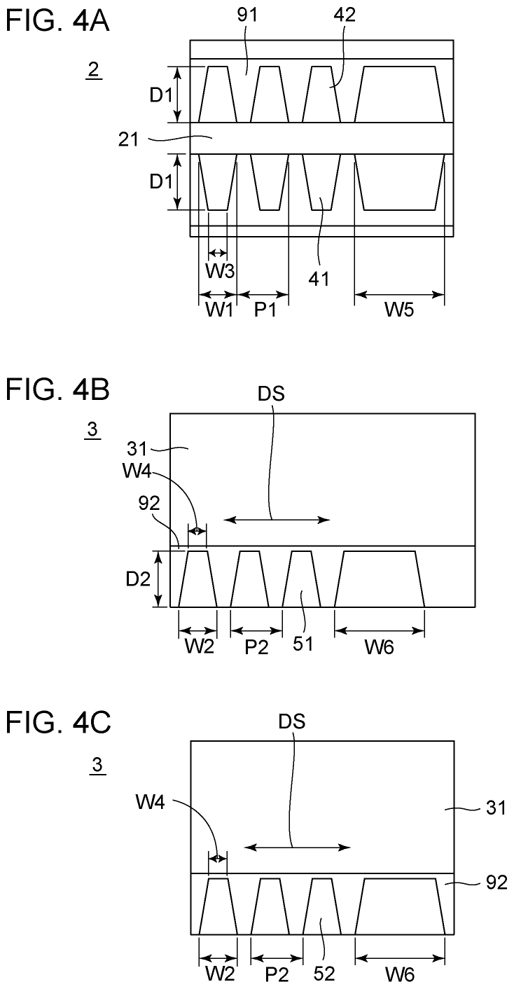

FIGS. 4A to 4C are schematic views illustrating a second embodiment of the connection module 1. According to the second embodiment, the shape of the connection electrode groups 51 and 52 is different from that of the first embodiment. However, since other points may be similar to those of the first embodiment, description of the other points is omitted.

As illustrated in FIG. 4A, at least one electrode included in the one connection electrode group 41 out of the connection electrode group 41 and the connection electrode group 51 has a distal portion and a proximal portion. The proximal portion is closer to the other connection electrode group 41 out of the connection electrode group 41 and the connection electrode group 51 than the distal portion. A length W1 of the proximal portion in the arrangement direction DM in which the plurality of electrodes included in the one connection electrode group 51 are arranged is greater than a length W3 of the distal portion in the arrangement direction DM.

As illustrated in FIG. 4A, at least one electrode included in the one connection electrode group 42 out of the connection electrode group 42 and the connection electrode group 52 has a distal portion and a proximal portion. The proximal portion is closer to the other connection electrode group 52 out of the connection electrode group 41 and the connection electrode group 51 than the distal portion. The length W1 of the proximal portion in the arrangement direction DM in which the plurality of electrodes included in the one connection electrode group 41 are arranged is greater than the length W3 of the distal portion in the arrangement direction DM.

As illustrated in FIG. 4B, at least one electrode included in the other connection electrode group 51 out of the connection electrode group 41 and the connection electrode group 51 has a distal portion and a proximal portion. The proximal portion is closer to the one connection electrode group 41 out of the connection electrode group 42 and the connection electrode group 52 than the distal portion. A length W2 of the proximal portion in the arrangement direction DS in which the plurality of electrodes included in the other connection electrode group 51 are arranged is greater than a length W4 of the distal portion in the arrangement direction DS.

As illustrated in FIG. 4C, at least one electrode included in the other connection electrode group 52 out of the connection electrode group 42 and the connection electrode group 52 has a distal portion and a proximal portion. The proximal portion is closer to the one connection electrode group 42 out of the connection electrode group 42 and the connection electrode group 52 than the distal portion. The length W2 of the proximal portion in the arrangement direction DS in which the plurality of electrodes included in the other connection electrode group 52 are arranged is greater than the length W4 of the distal portion in the arrangement direction DS.

As illustrated in FIG. 4A, in order that the connection electrode groups 41 and 42 of the main circuit board 2 to be connected to the ground lines of the sub-circuit board 3 correspond to a larger current, a width W5 of the electrodes to be connected to the ground lines is increased compared to the width W1 of the electrodes to be connected to the signal lines. For example, the width W5 may be greater than or equal to twice the width W1 (W5≥2×W1). As illustrated in FIGS. 4B and 4C, in order that the connection electrode groups 51 and 52 of the main circuit board 2 at positions to be connected to the ground line of the main circuit board 2 correspond to a larger current, a width W6 of the electrodes to be connected to the ground lines is increased compared to the width W2 of the electrodes to be connected to the signal lines. For example, the width W6 may be greater than or equal to twice the width W2 (W6≥2×W2).

### Third Embodiment

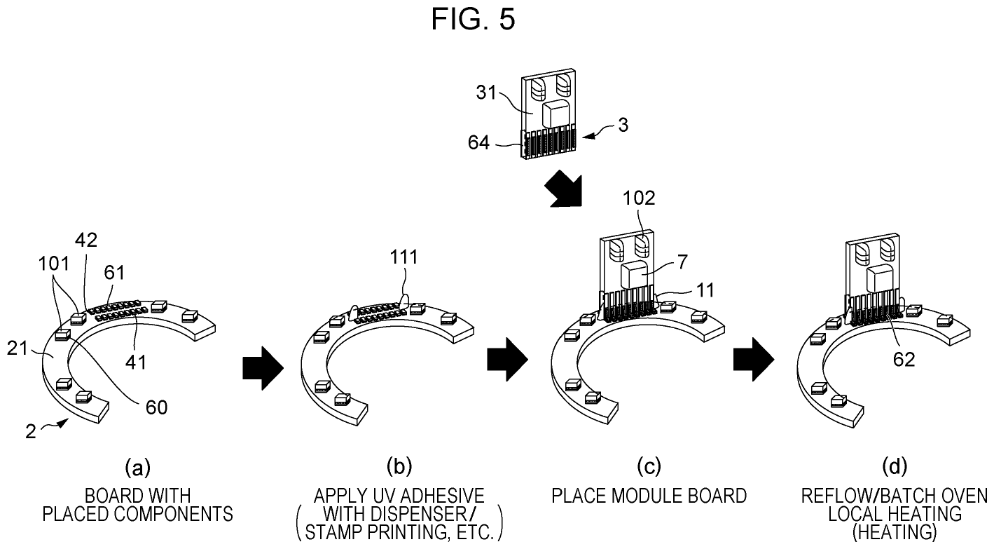

As a third embodiment, a method for manufacturing the circuit module is described. FIGS. 5(a) to 5(d) are schematic views illustrating an example of the method for manufacturing the circuit module.

FIG. 5(a) illustrates the main circuit board 2 before the sub-circuit board 3 is supplied. The main circuit board 2 includes the plurality of connection electrodes 40, 41, and 42. The connection electrodes 40, 41, and 42 are electrodes formed of electrically conductive metal, for example, copper and serve as, for example, signal electrodes, power supply electrodes, ground electrodes, or dummy electrodes. The main circuit board 2 is a rigid board formed of an insulating material such as epoxy resin. A solder resist film (not illustrated) may be provided on the main circuit board 2. In so doing, openings are formed at positions corresponding to the connection electrodes 40, 41, and 42 in the solder resist film. The relationships between the connection electrodes 40, 41, and 42 and a solder resist may be so-called solder mask defined (SMD) or so-called non-solder mask defined (NSMD).

Precoated solder 61 formed at the same time when the connection electrodes 40 and the electronic components 101 are placed and joined to each other with the solder 60 is formed on the connection electrode groups 41 and 42.

FIG. 5(b) illustrates a step of forming resin members 111 for fixing the sub-circuit board 3 so as to prevent deviation of the position of the sub-circuit board 3 or inclination of the sub-circuit board 3 after the sub-circuit board 3 has been placed on the main circuit board 2. The resin members 111 are applied to positions where both ends of the sub-circuit board 3 are disposed. The resin members 111 can be supplied, for example, with screen printing or a dispenser. Furthermore, flux (not illustrated) is applied onto the precoated solder 61 on the connection electrode groups 41 and 42. The flux can be supplied with screen printing or a dispenser.

FIG. 5(c) illustrates a step of placing the sub-circuit board 3 on the main circuit board 2. With a mounter or the like, the sub-circuit board 3 is placed so as to be astride the connection electrode groups 41 and 42 at a position corresponding to the predetermined connection electrode groups 51 and 52. The sub-circuit board 3 includes the plurality of connection electrodes 50, 51, and 52. The connection electrodes 50, 51, and 52 are electrodes formed of electrically conductive metal, for example, copper and serve as, for example, signal electrodes, power supply electrodes, ground electrodes, or dummy electrodes. The sub-circuit board 3 is a rigid board formed of an insulating material such as epoxy resin. A solder resist film (not illustrated) may be provided on the sub-circuit board 3. In so doing, openings are formed at positions corresponding to the connection electrodes 50, 51, and 52 in the solder resist film. The relationships between the connection electrodes 50, 51, and 52 and the solder resist may be so-called SMD or so-called NSMD. The precoated solder 61 formed at the same time when the connection electrodes 50, the integrated-circuit component 7, and the electronic components 102 are placed and joined with the solder 60 are formed on the connection electrode groups 51 and 52.

FIG. 5(d) illustrates the steps of heating the precoated solder 61, heating to a temperature higher than or equal to the melting point of the solder, melting and integrating the precoated solder 61 on the connection electrode groups 41 and 42 and the precoated solder 61 on the connection electrode groups 51 and 52, and cooling the integrated precoated solder 61 to a temperature lower than the melting point of the solder, and solidifying the cooled precoated solder 61. When the precoated solder 61 is integrated, and the solder is solidified, the main circuit board 2 and the sub-circuit board 3 are electrically and mechanically connected to each other through the solder 62. The steps of heating and cooling the solder paste can be performed with, for example, a reflow oven or a batch-type oven.

The circuit module 1 can be manufactured with the above-described steps.

Since the connection electrodes on the main circuit board 2 are joined to the connection electrodes on both the surfaces of the sub-circuit board 3 with the solder, the joint portion of the circuit module has a high strength, and the reliability of the joint of the circuit module can be improved.

### Fourth Embodiment

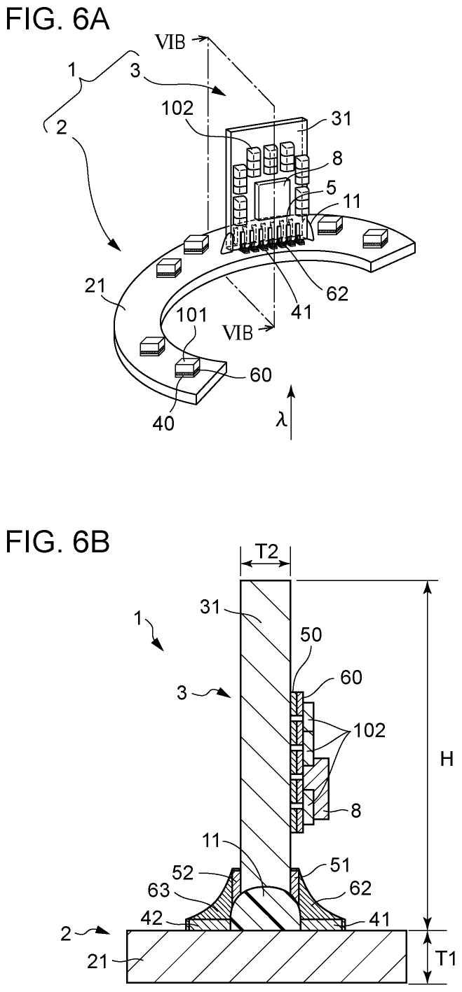

FIGS. 6A and 6B are schematic views illustrating a fourth embodiment of the circuit module 1. FIG. 6A is a perspective view illustrating an example of the fourth embodiment, and FIG. 6B is a sectional view taken along plane VIB (a rectangular plane indicated by an outline of a two-dot chain line) of FIG. 6A.

The power supply IC 8 and the required electronic components 102 that are the electronic components of the driver circuit system are placed on the sub-circuit board 3, and the other electronic components 101 of the system circuitry and the like and the other electronic components 101 are placed on the main circuit board 2. The integrated-circuit component 8 is an example of the integrated-circuit component 7 shown in FIG. 1B. The electronic components 102 mainly include chip components of the capacitors and have a cuboidal shape. The largest component in the sub-circuit board 3 is the integrated-circuit component 8 that is the power supply IC. The integrated-circuit component 8 that is the power supply IC is disposed at a position that is near the center of the sub-circuit board 3 and close to the main circuit board 2. Thus, the center of gravity of the sub-circuit board 3 is close to the main circuit board 2. Furthermore, many passive components 102 such as capacitors are disposed around the integrated-circuit component 8 that is the power supply IC for the power supply system circuit such that the longitudinal direction of the cuboidal electronic components extends along the optical axis OA (for example, extends parallel to the optical axis OA). Other configurations are similar to those of the first embodiment.

Since the large electronic components are disposed near the center of the sub-circuit board 3, deformation of the sub-circuit board 3 near the center caused when the sub-circuit board 3 is subjected to a drop impact or the like can be suppressed. Since the center of gravity of the sub-circuit board 3 is close to the main circuit board 2, a moment force applied with the solder joint portion 62 as the fulcrum when the sub-circuit board 3 is subject to drop impact or the like can be reduced. Since the deformation of the sub-circuit board 3 can be suppressed, and the moment force applied with the solder joint portion 62 as the fulcrum can be reduced, forces applied to the solder 62 can be reduced. Accordingly, the joint portion has a high strength, and the reliability of the joint of the circuit module can be improved.

### Fifth Embodiment

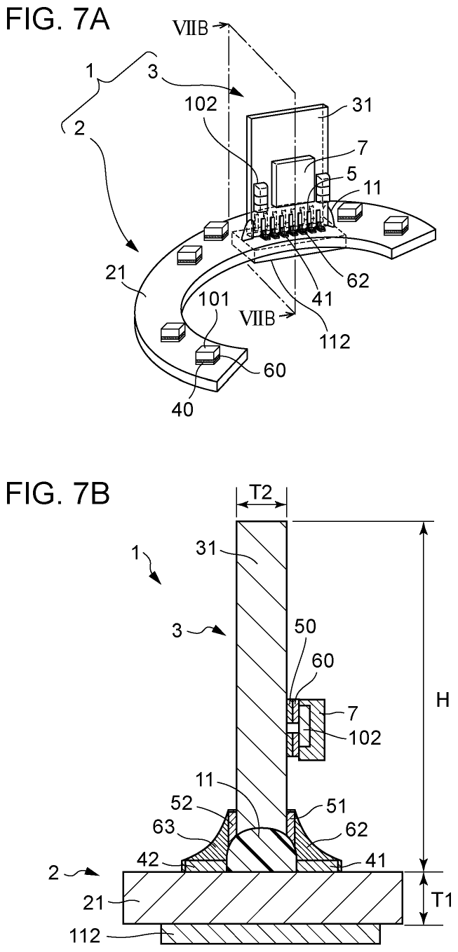

FIGS. 7A and 7B are schematic views illustrating a fifth embodiment of the circuit module 1. FIG. 7A is a perspective view illustrating an example of the fifth embodiment, and FIG. 7B is a sectional view taken along plane VIIB (a rectangular plane indicated by an outline of a two-dot chain line) of FIG. 7A.

The electronic component 112 is disposed on a back surface side of the main circuit board 2 which is the opposite side of the main circuit board 2 from the surface of the main circuit board 2 facing the sub-circuit board 3. A connector is placed as the electronic component 112. Other configurations are similar to those of the first embodiment.

Since the electronic component 112 such as a connector or the like is disposed on the back surface side of the main circuit board 2 relative to the sub-circuit board 3, the deformation of the main circuit board 2 near the sub-circuit board 3 caused when the main circuit board 2 is subjected to a drop impact or the like can be suppressed. The forces applied to the solder 62 of the sub-circuit board 3 can be reduced. Accordingly, the joint portion has a high strength, and the reliability of the joint of the circuit module can be improved.

The electronic component 112 is disposed so as to cover the entirety of the back surface side of the main circuit board 2 relative to the sub-circuit board 3.

However, a plurality of electronic components may be disposed so as to cover the solder 62 at least near both the ends and the center of the sub-circuit board 3 where comparatively larger forces are applied to the solder 62 due to a drop impact or the like. Although the electronic components are disposed only on one of the surfaces of the sub-circuit board 3 according to the above-described embodiments, the electronic components may be disposed on both the surfaces of the sub-circuit board 3.

### Sixth Embodiment

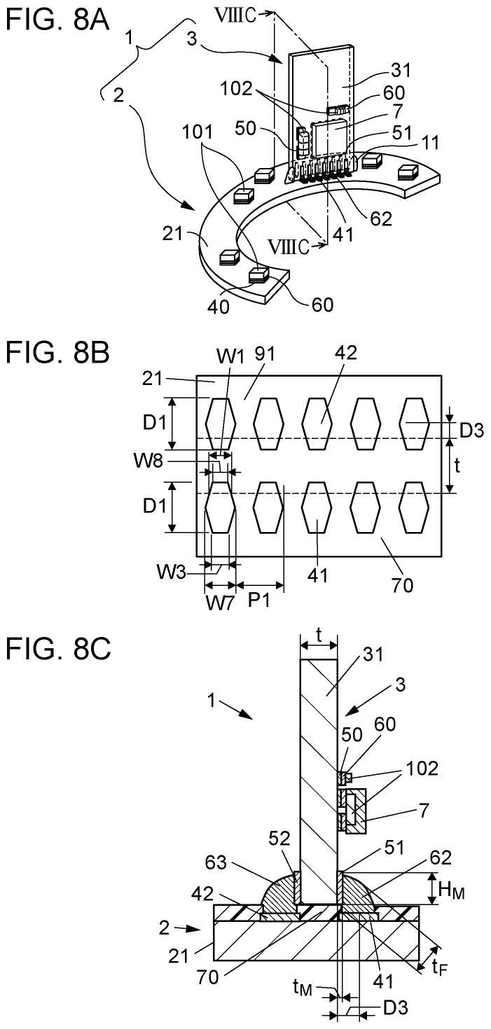

FIGS. 8A to 8C are schematic views illustrating a sixth embodiment of the circuit module 1. FIG. 8A is a perspective view illustrating the sixth embodiment, FIG. 8B is a plan view illustrating a subset of the connection electrodes of the printed wiring board when the wiring board 21 of FIG. 8A is seen from above, and FIG. 8C is a sectional view illustrating part of plane VIIIC of FIG. 8A illustrating the sixth embodiment. According to the sixth embodiment, the shape of the connection electrode groups 41 and 42 is different from that of the second embodiment. However, since other points may be similar to those of the second embodiment, description of the other points is omitted.

As illustrated in FIG. 8B, at least one electrode out of the connection electrode group 41 and the connection electrode group 42 has an intermediate portion having a width W7. The width W7 of the intermediate portion is greater than a width W8 of an electrode end portion on a side close to the connection electrode groups 51 and 52 and a width W3 of an electrode end portion on a side far from the connection electrode groups 51 and 52. Although the at least one electrode out of the connection electrode group 41 and the connection electrode group 42 in FIG. 8B has a hexagonal shape, the at least one electrode may have a quadrangular shape or a pentagonal shape. A width W1 of a proximal portion of the at least one electrode out of the connection electrode group 41 and the connection electrode group 42 is greater than the width W8 of the electrode end portion and smaller than the width W7 of the intermediate portion. The proximal portion having the width W1 is closer to the connection electrode groups 51 and 52 than the intermediate portion having the width W7 is, and the width W7 of the intermediate portion is greater than the width W1 of the proximal portion. The width W1 of the proximal portion is greater than the width W8 of the electrode end portion and smaller than the width W7 of the intermediate portion. A distal portion having the width W3 is far from the connection electrode groups 51 and 52 than the proximal portion having the width W1 and the intermediate portion having the width W7 are, and the width W3 of the distal portion is smaller than the width W1 of the proximal portion and smaller than the width W7 of the intermediate portion. For example, the width W1, W3, W7, W8 may be 0.05 mm or more, 0.1 mm or more, 1.0 mm or less, 0.5 mm or less, and/or 0.25 mm or less. A difference between the width W1 of the proximal portion and the width W7 of the intermediate portion may be 0.01 mm or more and/or 0.1 mm or less. For example, the width W7 may be 1.3 or more times the width W3 (W7≥1.3×W3), the width W7 may be 1.5 or more times the width W3 (W7≥1.5×W3), and/or the width W7 may be 2.0 or less times the width W3 (W7≤2.0×W3). For example, the width W7 may be 1.1 or more times the width W1 (W7≥1.1×W1), the width W7 may be 1.2 or more times the width W1 (W7≥1.2×W1), and/or the width W7 may be 1.5 or less times the width W1 (W7≤1.5×W1), the width W7 may be 1.4 or less times the width W1 (W7≤1.4×W1). For example, the width W1 may be 1.1 or more times the width W3 (W1≥1.1×W3), and/or, the width W1 may be 1.3 or less times the width W3 (W1≤1.3×W3). These examples of widths are suitable for both the reliability of circuit boards connection and the realization of high-density mounting.

Intermediate portions of the connection electrode group 41 and the connection electrode group 42 are disposed outside a placement-side end portion of the wiring board 31. A distance D3 between the placement-side end portion of the wiring board 31 on the wiring board 21 and the intermediate portion of the connection electrode groups 41 and 42 is, as illustrated in FIG. 4C, greater than a thickness direction t_{M} of the electrode groups 51 and 52 and smaller than a length direction H_{M} of the electrode groups 51 and 52.

When the intermediate portions having the width W7 are provided in the connection electrode group 41 and the connection electrode group 42, a larger amount of the solder aggregates to the intermediate portions, and a fillet thickness t_{F} of the solder increases. When the width W1 of the proximal portion is made to be smaller than the width W7 of the intermediate portion, a portion where the fillet thickness t_{F} increases can be disposed at an appropriate position. Furthermore, when the width W3 of the distal portion is made to be smaller than the width W7 of the intermediate portion, flowing of the solder in the intermediate portion to the distal portion can be suppressed. When the fillet thickness t_{F} increases as described above at an appropriate position, stress required to cause breaking of the solder increases. Accordingly, the reliability of the joint of the circuit module can be improved.

At least one electrode out of the connection electrode group 41 and the connection electrode group 42 has an overlap portion that overlaps the wiring board 31. Referring to FIG. 8B, a range in which the electrodes overlap the wiring board 31 (an overlapping range) is denoted as a thickness t of the wiring board 31. Parts of the connection electrode group 41 and the connection electrode group 42 existing in the overlapping range are overlap portions. The overlap portions of the connection electrode group 41 and the connection electrode group 42 include the electrode end portions having the width W8. A length D4 of the overlap portions is smaller than the length D1 of the connection electrode, for example, smaller than half D1. For example, although the length D4 is not shown in FIG. 8B, the length D4 can be represented by D4=(D1/2)−D3. Since portions to be soldered are mainly the proximal and the intermediate portions, the distance D3 can be greater than the length D4 in terms of an increase in joint strength. Since D3>(D1/2)−D3, D3>D1/4 is preferable.

### Seventh Embodiment

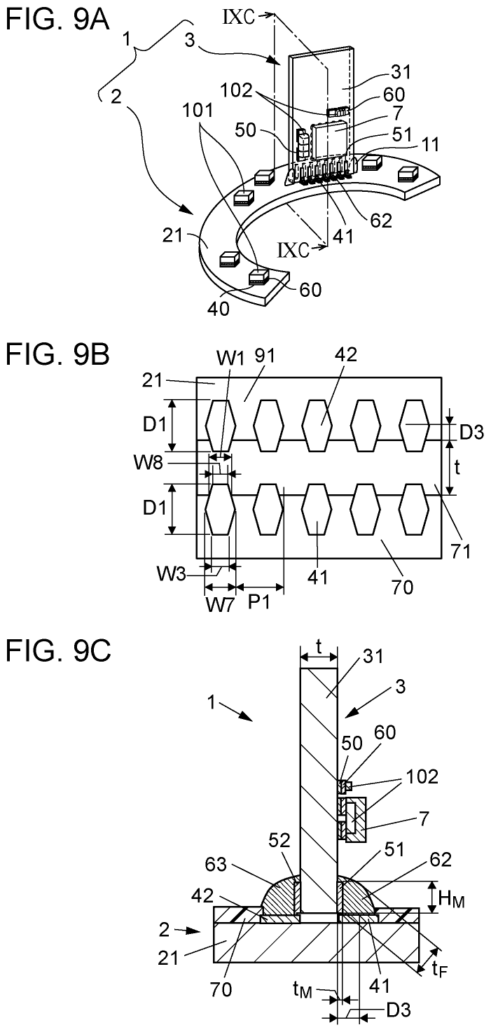

FIGS. 9A to 9C are schematic views illustrating a seventh embodiment of the circuit module 1. FIG. 9A is a perspective view illustrating the seventh embodiment, FIG. 9B is a plan view illustrating a subset of the connection electrodes of the printed wiring board when the wiring board 21 of FIG. 9A is seen from above, and FIG. 9C is a sectional view illustrating part of plane IXC of FIG. 9A illustrating the seventh embodiment. According to the seventh embodiment, the shape of a solder resist 70 is different from that of the sixth embodiment. However, since other points may be similar to those of the sixth embodiment, description of the other points is omitted.

As illustrated in FIG. 9B, the solder resist film is not formed in a region 71 in which the wiring board 21 is to be placed. As illustrated in FIG. 9C, when the distance between the upper surfaces of the connection electrode group 41 and the connection electrode group 42 and the lower surface of the connection electrode group 51 and the connection electrode group 52 is reduced, the fillet thickness t_{F} of the solder can be increased.

Accordingly, the reliability of the joint of the circuit module can be improved.

### Eighth Embodiment

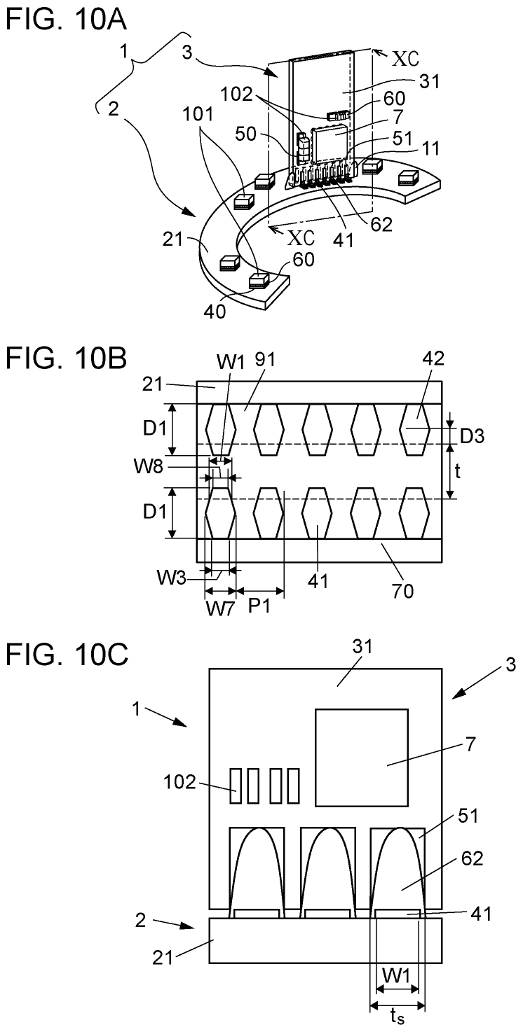

FIGS. 10A to 10C are schematic views illustrating an eighth embodiment of the circuit module 1. FIG. 10A is a perspective view illustrating the eighth embodiment, FIG. 10B is a plan view illustrating a subset of the connection electrodes of the printed wiring board when the wiring board 21 of FIG. 10A is seen from above, and FIG. 10C is a front view illustrating part of region XC of FIG. 10A illustrating the eighth embodiment. According to the eighth embodiment, the shape of the solder resist 70 is different from that of the seventh embodiment. However, since other points may be similar to those of the seventh embodiment, description of the other points is omitted.

As illustrated in FIG. 10B, the solder resist is not formed in an adjacent region adjacent to the connection electrode groups 41 and 42 wetted by the solder. The adjacent region is between the connection electrodes of the connection electrode groups 41 and 42 wetted by the solder. As illustrated in FIG. 10C, since the solder resist is not formed in the adjacent region of the connection electrode groups 41 and 42, side surfaces of the connection electrode groups 41 and 42 are wetted by the solder 62. When the side surfaces of the connection electrode groups 41 and 42 are coated with the solder 62, a width tₛ of the solder 62 becomes greater than the width of the connection electrode groups 41 and 42 (for example, the W7 of the intermediate portion). When the width tₛ of the solder increases, stress required to cause breaking of the solder increases.

Accordingly, the reliability of the joint of the circuit module can be improved.

### Ninth Embodiment

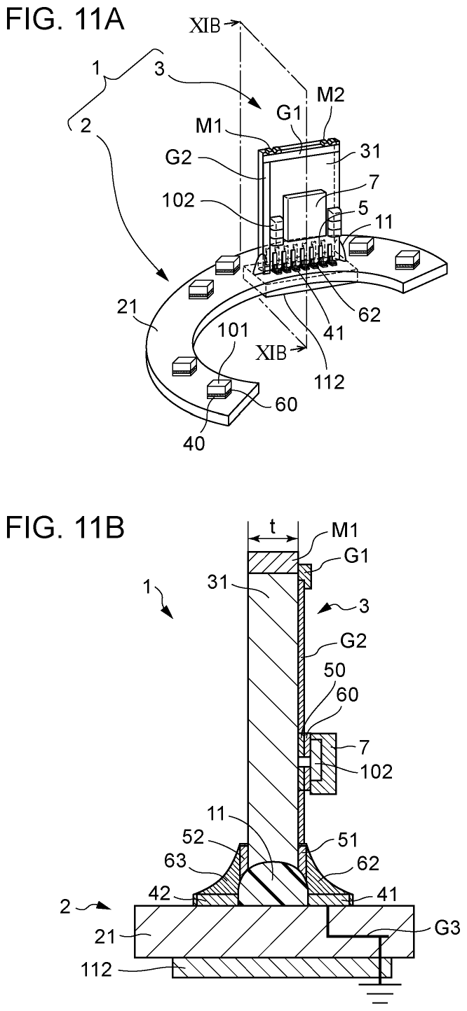

FIGS. 11A and 11B are schematic views illustrating a ninth embodiment of the circuit module 1. FIG. 11A is a perspective view illustrating an example of the ninth embodiment, and FIG. 11B is a sectional view taken along plane XIB (a rectangular plane indicated by an outline of a two-dot chain line) of FIG. 11A. According to the ninth embodiment, arc-shaped metal portions M1 and M2 extending to the main surfaces 303 and 304 and lines G1 and G2 are disposed near both the ends of the end surface 302 of the sub-circuit board 3 in the longitudinal direction. Since other points may be similar to those of the fifth embodiment, description of the other points is omitted.

The arc-shaped metal portions M1 and M2 extending to the main surfaces 303 and 304 are disposed near both the ends of the end surface 302 of the sub-circuit board 3 in the longitudinal direction. The lines G1 and G2 are disposed on the main surface 303 side of the sub-circuit board 3. With the lines G1 and G2, the metal portions M1 and M2 are connected to a ground (GND) line G3 in an internal layer of the of the main circuit board and a GND line (not illustrated) of the electronic component 112 through the solder 62.

It is sufficient that the material of the metal portions M1 and M2 be an electrically conductive material exhibiting a different reflectivity of light from that of the material of the wiring board of the sub-circuit board 3. Cu or Au plated on the surface can be used.

In placing the sub-circuit board 3 on the main circuit board 2 (FIG. 5(c)), clear contrast is obtained when image processing is performed to perform alignment while the metal portions M1 and M2 are observed from right above with an optical microscope or the like. Thus, the position of the sub-circuit board 3 can be accurately determined in the middle of the connection electrode groups 41 and 42 on the main circuit board 2. Thus, fillet shapes of the solder 62 and the solder 63 become uniform, and the difference between forces applied to the solder 62 and the solder 63 can be reduced. Accordingly, the joint portion has a high strength, and the reliability of the joint of the circuit module can be improved. Furthermore, when the metal portions M1 and M2 are connected to the GND line of the main circuit board 2, generation of noise by the metal portions M1 and M2 can be reduced.

### Tenth Embodiment

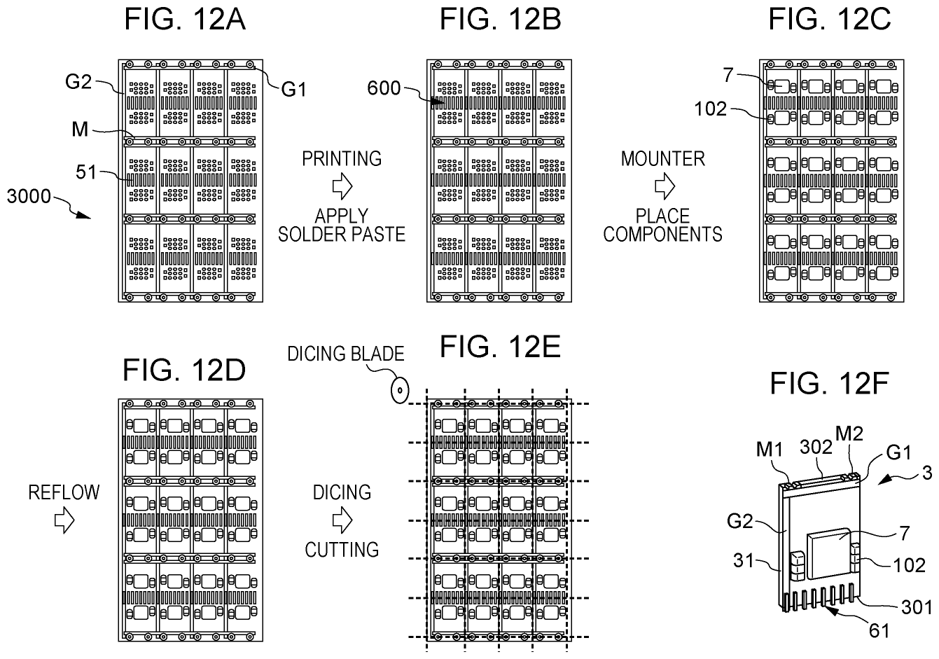

As a tenth embodiment, a method for manufacturing the sub-circuit board 3 according to the ninth embodiment is described. FIGS. 12A to 12F are schematic views illustrating an example of the method for manufacturing the sub-circuit board 3.

FIG. 12A illustrates a base board 3000 of the sub-circuit board 3 before cutting. The base board 3000 includes a plurality of connection electrodes 50, 51, and 52, the lines G1 and G2, and through holes M. The connection electrodes 50, 51, and 52 and the lines G1 and G2 are electrodes formed of electrically conductive metal, for example, copper and serve as, for example, signal electrodes, power supply electrodes, ground electrodes, or dummy electrodes. Electrically conductive plating metal, for example, gold is formed in the through holes M and connected to lines G1. The sub-circuit board 3 is a rigid board formed of an insulating material such as epoxy resin. The solder resist film (not illustrated) may be provided on the sub-circuit board 3. In so doing, openings are formed at positions corresponding to the connection electrodes 50, 51, and 52 and the lines G1 and G2 in the solder resist film. The relationships of the connection electrodes 50, 51, and 52 and the lines G1 and G2 with the solder resist may be so-called SMD or NSMD.

Electronic components may be embedded in advance in the through holes of the base board 3000. The electronic components to be embedded can be chip components that can suppress noise such as capacitors, resistors, or ferrite beads.

FIG. 12B illustrates a step of forming solder paste 600 in parts of the connection electrodes 50, the connection electrode groups 51 and 52, and the lines G2. The solder paste 600 can be supplied, for example, with screen printing or a dispenser.

FIG. 12C illustrates a step of placing the electronic components on the base board 3000. The integrated-circuit component 7 and the electronic components 102 are placed on the connection electrodes 50. The step of placing the electronic components can be performed with, for example, a mounter. At this time, the members may be placed on the solder paste on the lines G2 (not illustrated).

FIG. 12D illustrates the steps of heating the solder paste 600, heating to a temperature higher than or equal to the melting point of the solder, cooling to a temperature lower than the melting point of the solder, and connecting the connection electrodes 50 and the electronic components 102 and the like being solidified to each other. The sub-circuit boards 3 are electrically and mechanically connected to the integrated-circuit component 7 and the electronic components 102 through the solder 60. The precoated solder 61 formed at the same time when the connection electrodes 50 and the electronic components 102 or the like are joined to each other with the solder 60 is formed on parts of the connection electrode groups 51 and 52 and the lines G2. The steps of heating and cooling the solder paste can be performed with, for example, a reflow oven or a batch-type oven.

FIG. 12E illustrates a step of performing dicing by cutting the base board 3000 into the sub-circuit boards 3. When the base board 3000 is cut in the X direction and the Y direction along the dotted lines in FIG. 12E, the main surfaces 303 and 304 and the end surfaces 301 and 302 of the sub-circuit boards 3 can be formed. A perspective view of the sub-circuit board 3 after the cutting is illustrated in FIG. 12F.

When central portions of the through holes M are cut in the X direction, the arc-shaped metal portions M1 and M2 extending to the main surfaces 303 and 304 are formed on the end surface 302. Furthermore, the metal portions M1 and M2 are connected to the line G1, and the line G1 is connected to the line G2. The cutting is performed with a dicer, a wire saw, or the like.

Through the steps as described above, the sub-circuit board 3 can be manufactured. The metal portions M1 and M2 are each seen as an independent rectangle in top view of the end surface 302. Since the metal portions M1 and M2 are formed of gold, clear contrast is obtained and binarization is easily performed. Thus, the middle point and the center-of-gravity point of each rectangle can be accurately calculated with the image processing. Accordingly, when the sub-circuit board 3 is placed on the main circuit board 2, the connection electrode groups 51 and 52 are accurately aligned with the connection electrode groups 41 and 42 by using the metal portions M1 and M2 and alignment marks (not illustrated) of the main board. As a result, the fillet shapes of the solder 62 and the solder 63 become uniform, and the difference between forces applied to the solder 62 and the solder 63 can be reduced. Accordingly, the joint portion has a high strength, and the reliability of the joint of the circuit module can be improved. Furthermore, when the metal portions M1 and M2 are connected to the GND line of the main circuit board 2, generation of noise by the metal portions M1 and M2 can be reduced.

### Eleventh Embodiment

### Alignment Mark and Ferrite Beads

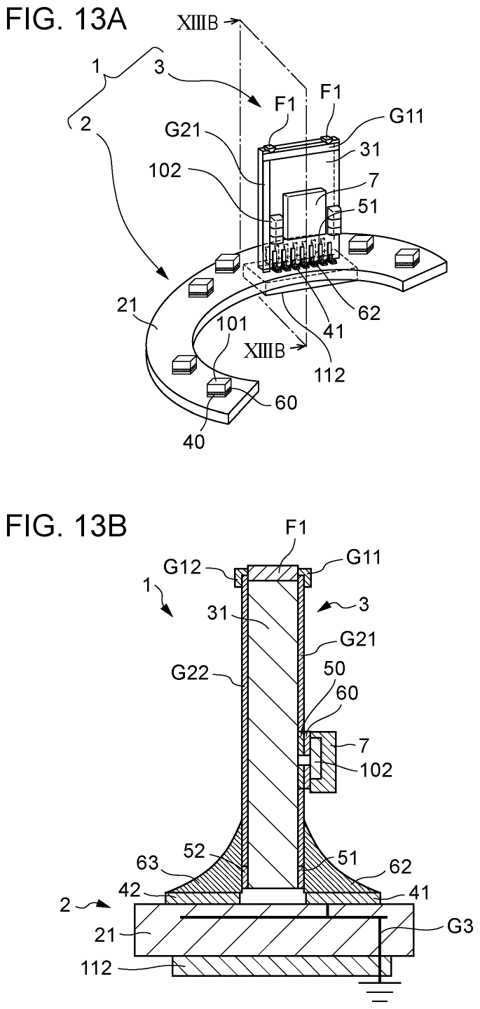

FIGS. 13A and 13B are schematic views illustrating an eleventh embodiment of the circuit module 1. FIG. 13A is a perspective view illustrating an example of the eleventh embodiment, and FIG. 13B is a sectional view taken along plane XIIIB (a rectangular plane indicated by an outline of a two-dot chain line) of FIG. 13A.

According to the eleventh embodiment, semicircular ferrite beads F1 are disposed in an arc shape extending to the main surfaces 303 and 304 near both the ends of the end surface 302 of the sub-circuit board 3 in the longitudinal direction. Electrodes are respectively formed at both the ends of each of the ferrite beads F1. A line G11 and a line G12 are respectively connected to a line G21 and a line G22. Other points may be similar to those of the ninth embodiment, description of the other points is omitted.

The semicircular ferrite beads are disposed by embedding, in advance, cylindrical ferrite beads in each of which the electrodes are respectively formed at both the ends in the through holes M as the electronic components in the method for manufacturing the sub-circuit board 3 according to the tenth embodiment. When the base board 3000 is cut, each cylindrical ferrite bead is cut into halves, and accordingly, the ferrite beads with exposed semicircular cut ends can be disposed.

One of the electrodes of the ferrite bead F1 is connected to the internal layer line G3 of the main circuit board 2 at least through the lines G11 and G12, the lines G21 and G22, and the solder 62 and 63 and connected to a GND line (not illustrated) of a connector 112.

When the alignment is performed by using the electrodes at both the ends of two ferrite beads F1, placement accuracy of the sub-circuit board 3 can be improved. Thus, fillet shapes of the solder 62 and the solder 63 become uniform, and the difference between forces applied to the solder 62 and the solder 63 can be reduced. As a result, the joint portion has a high strength, and the reliability of the joint of the circuit module can be improved. Furthermore, generation of noise can be reduced with the ferrite beads F1.

### Twelfth Embodiment

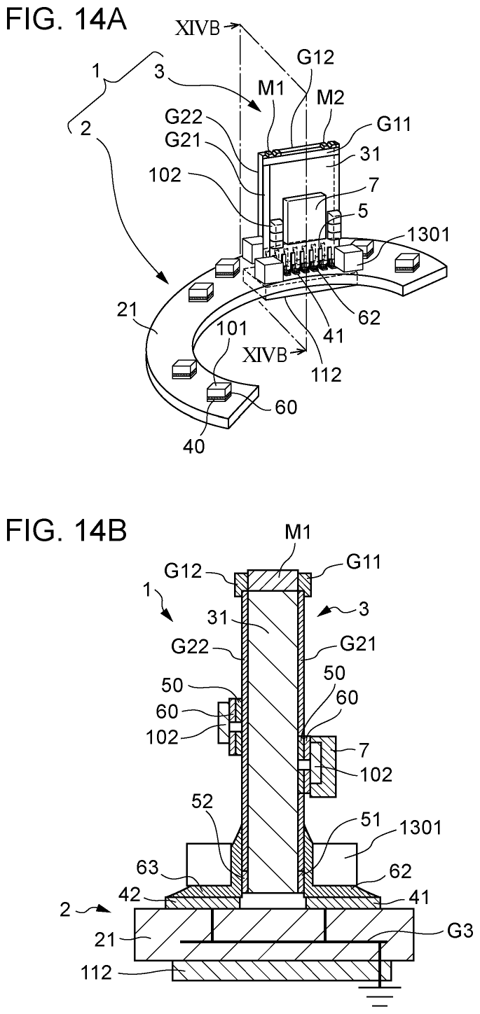

FIGS. 14A and 14B are schematic views illustrating a twelfth embodiment of the circuit module 1. FIG. 14A is a perspective view illustrating an example of the twelfth embodiment, and FIG. 14B is a sectional view taken along plane XIVB (a rectangular plane indicated by an outline of a two-dot chain line) of FIG. 14A.

According to the twelfth embodiment, self-support assisting members 1301 are disposed at both the ends on both the surfaces of the sub-circuit board 3. Furthermore, the lines G11, G12, G21, and G22 are disposed on each of the main surfaces of the sub-circuit board 3 so as to be connected to the GND line G3 of the internal layer of the main circuit board 2. Other points may be similar to those of the ninth embodiment, description of the other points is omitted.

Regarding the self-support assisting members 1301, in the method for manufacturing the sub-circuit board 3 according to the tenth embodiment, self-support assisting members (not illustrated) corresponding to four self-support assisting members 1301 are placed in advance on the base board 3000 with the mounter or the like so that the self-support assisting members 1301 are disposed at both the ends on both the surfaces of the sub-circuit board 3. After that, the self-support assisting members are cut into four pieces in the step of cutting, and thereby the self-support assisting members 1301 are disposed at both the ends on both the surfaces of the sub-circuit board 3. The material of the self-support assisting members 1301 may be an electronic component such as a chip component, an insulating material such as epoxy resin, or an electrically conductive material such as copper or solder. The material of the self-support assisting members 1301 can be a material that can be joined to the electrode members and the wiring members of the main circuit board 2 and the sub-circuit board 3 with solder. The size of the self-support assisting members 1301 is appropriately set in accordance with the dimensions of the sub-circuit board 3 such as a thickness and a height, a space on the main circuit board 2 side, and so forth. Although the self-support assisting members 1301 can be placed at both the ends on both the surfaces of the sub-circuit board 3 in consideration of a self supporting ability, the self-support assisting members 1301 may be disposed in consideration of the numbers and the positions appropriately.

In placing the sub-circuit board 3 on the main circuit board 2 (FIG. 5(c)), clear contrast is obtained when image processing is performed to perform alignment while the metal portions M1 and M2 are observed from right above with an optical microscope or the like. Thus, the position of the sub-circuit board 3 can be accurately determined in the middle of the connection electrode groups 41 and 42 on the main circuit board 2. Furthermore, with the self-support assisting members 1301, the self supporting ability in placing the sub-circuit board 3 is improved. Accordingly, the presence or absence of the resin members 111 for prevention of toppling or the like of the sub-circuit board 3 and reinforcement can be selected according to need. The step of forming the resin members 111 can be deleted.

In placing the sub-circuit board 3 on the main circuit board 2 (FIG. 5(c)), clear contrast is obtained when image processing is performed to perform alignment while the metal portions M1 and M2 are observed from right above with an optical microscope or the like. Thus, the position of the sub-circuit board 3 can be accurately determined in the middle of the connection electrode 41 and 42 on the main circuit board 2. Thus, fillet shapes of the solder 62 and the solder 63 become uniform, and the difference between forces applied to the solder 62 and the solder 63 can be reduced. Accordingly, the joint portion has a high strength, and the reliability of the joint of the circuit module can be improved. Furthermore, when the metal portions M1 and M2 are connected to the internal layer GND line G3 of the main circuit board 2 through the lines G11, G12, G21, and G22, the connection electrode groups 51, 52, 41, and 42, and the solder 62 and 63, generation of noise by the metal portions M1 and M2 can be reduced.

### EXAMPLES

### Example 1

The circuit module 1 illustrated in FIGS. 2A and 2B was manufactured with the method of manufacturing illustrated with reference to FIGS. 5(a) to 5(d). The integrated-circuit component 7 and the electronic components 102 such as resistors as the system circuitry are placed on the sub-circuit board 3, and the other electronic components 101 including the electronic components of the driver circuit system are placed on the arc-shaped main circuit board 2.

Referring to FIG. 5(a), a flame retardant type 4 (FR4) four-layer printed wiring board is used as the wiring board 21 of the arc-shaped main circuit board 2. The outline size of this board is as follows: the outer diameter is about 54.0 mm; the inner diameter is about 49.0 mm; and the thickness is 0.8 mm. A total of 100 connection electrodes including 50 electrodes as the connection electrode group 41 and 50 electrodes as the connection electrode group 42 are formed on the surface layer of the wiring board as follows: the thickness of copper is 0.015 mm; the width W1 is 0.15 mm; the pitch P1 of the adjacent connection electrodes is 0.25 mm; and the length D1 is 0.20 mm. The precoated solder 61 formed when the electronic components 101 are placed on the connection electrodes 40 and joined to the connection electrodes 40 with the solder 60 is formed on the connection electrode groups 41 and 42. The precoated solder 61 has a composition of balance-tin the melting point of which is 220° C., 3-silver, and 3-copper.

Next, as illustrated in FIG. 5(b), the resin members 111 of ϕ1.5 mm were applied with a dispenser at positions of the wiring board 21 at which both the ends of the sub-circuit board 3 were to be disposed outside the connection electrode groups 41 and 42.

As the resin members 111, ultraviolet (UV) resin cured after irradiation with UV was used. Furthermore, flux (not illustrated) was applied with a dispenser onto the precoated solder 61 on the connection electrode groups 41 and 42. The main circuit board 2 and the sub-circuit board 3 are fixed to each other with the resin members 111. The resin members 111 reinforce the joint with the solder.

Next, as illustrated in FIG. 5(c), with a mounter or the like, the sub-circuit board 3 fabricated in advance was placed so as to be astride the connection electrode groups 41 and 42 of the arc-shaped main circuit board 2 at a position corresponding to the connection electrode groups 51 and 52 of the sub-circuit board 3. At this time, both the ends of the sub-circuit board 3 are positioned near the centers of the resin members 111.

Before the sub-circuit board 3 was placed, UV light was radiated to the resin members 111 for about 20 seconds (not illustrated).

An FR4 four-layer printed wiring board is used as the wiring board 31. The outline size of this board is as follows: the width L is about 14.0 mm; the height H is about 5.0 mm; and the thickness T2 is 0.8 mm. A total of 100 connection electrodes including 50 electrodes as the connection electrode groups 51 and 50 electrodes as the connection electrode groups 52 are formed on the surface layers of the front surface and the back surface of the wiring board 31 as follows: the thickness of copper is 0.015 mm; the width W2 is 0.15 mm; the pitch P2 of the adjacent connection electrodes is 0.25 mm; and a length D2 is 0.25 mm. In order that the sub-circuit board 3 can be fixed with the resin members 111, the connection electrode groups 51 and 52 are formed so as to be spaced from each end by 0.75 mm. The precoated solder 61 formed when the integrated-circuit component 7 and the electronic components 101 are placed on the connection electrodes 50 and joined with the solder 60 are formed on the connection electrode groups 51 and 52. The precoated solder 61 has a composition of balance-tin the melting point of which is 220° C., 3-silver, and 3-copper.

After the placement of the sub-circuit board 3, the UV resin is cured before the following heating step and the sub-circuit board 3 is fixed. Thus, toppling of the sub-circuit board 3 or deviation of the placement position does not occur even in the hot air during the reflow.

As long as toppling of the sub-circuit board 3 or deviation of the placement position does not occur during conveyance to the following heating step or the heating step, The resin members 111 are not limited to the UV resin, and thermosetting resin may be used.

Next, as illustrated in FIG. 5(d), the precoated solder 61 was heated, heating was performed to a temperature higher than or equal to the melting point of the solder, the precoated solder 61 on the connection electrode groups 41 and 42 and the connection electrode groups 51 and 52 were melted and integrated, the integrated precoated solder 61 was cooled to a temperature lower than the melting point of the solder so as to be solidified. When the precoated solder 61 is integrated, and the solder is solidified, the arc-shaped main circuit board 2 and the sub-circuit board 3 are electrically and mechanically connected to each other through the solder 62.

Thus, the circuit module 1 was fabricated in which the arc-shaped main circuit board 2 and the sub-circuit board 3 are joined to each other with the solder. Since the circuit module 1 is joined with the solder, the joint portion has a high strength, and the reliability of the joint of the circuit module can be improved.

Furthermore, a solder joint length is at least about 15 mm corresponding to 100 lands of the land width W1=W2=0.15 mm. Since the solder becomes wet and is spread to the entirety including side surfaces of the lands. Thus, the solder joint length is greater than or equal to 15 mm. Accordingly, the solder joint length can be greater than 14.0 mm which is the width L of the sub-circuit board 3. This is a state in which the entirety of the width of the sub-circuit board 3 is joined with the solder, and accordingly, the joint strength increases.

A plurality of lenses of the optical systems 100 and the circuit module 1 were mounted in the lens barrel 400 to produce the optical device 500. Optical performance is sufficiently ensured even after drop impact testing.

### Example 2

FIGS. 4A to 4C are schematic views of the other embodiment of the connection electrodes of the sub-circuit board 3 and the arc-shaped printed wiring board of the circuit module according to the present disclosure. FIG. 4A is a plan view illustrating the connection electrode groups 41 and 42 of the arc-shaped printed wiring board. FIG. 4B is a plan view illustrating the connection electrode group 51 of the sub-circuit board 3, FIG. 4C is a plan view illustrating the connection electrode group 52 on the back surface side of the sub-circuit board 3.

FIGS. 4A and 4A′ are schematic views of the connection electrodes of the sub-circuit board 3. The connection electrode groups 51 and 52 are formed on the surface layers of the front surface and the back surface of the wiring board 31. The connection electrode groups 51 and 52 have a trapezoidal shape having the following dimensions: the width W2 near the arc-shaped main circuit board 2 is 0.16 mm; the width W4 far from the arc-shaped main circuit board 2 is 0.10 mm; the pitch P2 of the adjacent connection electrodes is 0.25 mm; and the length D2 is 0.25 mm.

FIG. 4B is a schematic view of the connection electrodes of the arc-shaped main circuit board 2. The connection electrode groups 41 and 42 are formed on the surface layer of the wiring board 21. The connection electrodes of the connection electrode groups 41 and 42 have a trapezoidal shape having the following dimensions: the width W1 is 0.16 mm; a width W4 is 0.10 mm; the pitch P1 of the adjacent connection electrodes is 0.25 mm; and the length D1 is 0.25 mm. The size of the connection electrodes to be connected to the ground line is increased by connecting two adjacent connection electrodes.

With the other structures set to be similar to example 1, the circuit module 1 was fabricated in which the arc-shaped main circuit board 2 and the sub-circuit board 3 are joined to each other with the solder.

The solder joint length is at least greater than or equal to 17 mm because the land width W1=W2=0.16 mm, the joint length of both the ends is twice the length of P1=P2, and solder becomes wet and is spread to the entirety including the side surfaces of the lands. The solder joint length can further increase from 14.0 mm which is the width L of the sub-circuit board 3. Furthermore, since the electrode lands have a trapezoidal shape, the thickness of the precoated solder 61 increases at the longer bottom side of the trapezoid due to an aggregating property of the solder. This increases the thickness of the solder 62, particularly the thickness of the solder at positions where the connection electrodes of the arc-shaped main circuit board 2 and the sub-circuit board 3 are closest to each other. Accordingly, the joint strength can be further improved. In this way, the circuit module 1 was fabricated in which the arc-shaped main circuit board 2 and the sub-circuit board 3 are joined to each other with the solder. Since the circuit module 1 is joined with the solder, the joint portion has a high strength, and the reliability of the joint of the circuit module can be improved.

A plurality of lens optical systems 100 and the circuit module 1 were mounted in the lens barrel 400 to produce the optical device 500. Optical performance is sufficiently ensured even after the drop impact testing.

### Example 3

FIGS. 8A to 8C are schematic views illustrating the sixth embodiment of the connection electrodes of the arc-shaped printed wiring board according to the present disclosure. FIG. 8A is a perspective view illustrating the sixth embodiment, FIG. 8B is a plan view illustrating the connection electrodes of the arc-shaped printed wiring board, and FIG. 8C is a sectional view taken along plane VIIIC of FIG. 8A illustrating the sixth embodiment.

FIG. 8B is a schematic view of the connection electrodes of the arc-shaped printed wiring board. The connection electrode groups 41 and 42 are formed on the surface layer of the wiring board 21. The connection electrode groups 41 and 42 have a hexagonal shape and have the following dimensions: the length D1 is 0.25 mm; the width W8 at end portions of the connection electrode groups 41 and 42 close to the sub-circuit board 3 is 0.10 mm; the width W3 at end portions of the connection electrode groups 41 and 42 far from the sub-circuit board 3 is 0.10 mm; the width W7 at intermediate portions of the connection electrode groups 41 and 42 is 0.16 mm at a position spaced, by 0.125 mm (D1/2), from the both ends portions of the connection electrodes 41 and 42; the distance D3 between end portions of the wiring board 31 to be placed on the wiring board 21 and intermediate portions of the connection electrode groups 41 and 42 is 0.08 mm; and the length D4 of an overlap portion is 0.045 mm; the width W8 at proximal portions of the connection electrode groups 41 and 42 is 0.12 mm at a position spaced, by 0.08 mm (D3), from the intermediate portions, and spaced, by 0.045 mm (D4), from the end portions of the connection electrode groups 41 and 42 close to the sub-circuit board 3; the pitch P1 of the adjacent connection electrodes is 0.25 mm.

FIG. 8C is a sectional view taken along plane VIIIC of FIG. 8A illustrating the sixth embodiment.

With the other structures set to be similar to example 1, the circuit module 1 was fabricated in which the arc-shaped main circuit board 2 and the sub-circuit board 3 are joined to each other with the solder.

When the maximum width W3 of the electrode lands is disposed outside the end portions of the wiring board 31, a large amount of the solder is aggregated to the maximum width W3 of the electrode lands, and the sectional shape of the solder 62 becomes an arc shape. Accordingly, the thickness of the fillet t_{F} of the solder 62 becomes larger than that of embodiment 2, and the joint strength can be further improved. In this way, the circuit module 1 was fabricated in which the arc-shaped main circuit board 2 and the sub-circuit board 3 are joined to each other with the solder. Since the circuit module 1 is joined with the solder, the joint portion has a high strength, and the reliability of the joint of the circuit module can be improved.

A plurality of lens optical systems 100 and the circuit module 1 were mounted in the lens barrel 400 to produce the optical device 500. Optical performance is sufficiently ensured even after the drop impact testing.

### Example 4

FIGS. 9A to 9C are schematic views illustrating the seventh embodiment of the connection electrodes of the arc-shaped printed wiring board according to the present disclosure. FIG. 9A is a perspective view illustrating the seventh embodiment, FIG. 9B is a plan view illustrating the connection electrodes of the arc-shaped printed wiring board, and FIG. 9C is a sectional view taken along plane IXC of FIG. 9A illustrating the seventh embodiment.

FIG. 9B is a schematic view of the connection electrodes of the arc-shaped printed wiring board. A region 70 where the solder resist is formed and the region 71 where the solder resist is not formed exist on the surface layer of the wiring board 21. The size of the region 71 where the solder resist is not formed is as follows: the length is about 14.5 mm; and a width is about 0.85 mm. The position of the center of gravity of the region 71 where the solder resist is not formed and the position of the center of gravity of a region where the wiring board 31 is to be placed are coincident with each other.

With the other structures set to be similar to example 1, the circuit module 1 was fabricated in which the arc-shaped main circuit board 2 and the sub-circuit board 3 are joined to each other with the solder.

Since the region where the solder resist is not formed is greater than the region where the sub-circuit board 3 is to be placed, the sub-circuit board 3 penetrates more deeply when the joint with the solder is performed. Referring to FIG. 9C, the distance between the lower surfaces of the connection electrode groups 51 and 52 and the upper surfaces of the connection electrode groups 41 and 42 is reduced to about 10 m.

Thus, the sectional shape of the solder 62 becomes an arc shape. Accordingly, the thickness of the fillet t_{F} of the solder 62 becomes larger than that of embodiment 2, and the joint strength can be further improved. In this way, the circuit module 1 was fabricated in which the arc-shaped main circuit board 2 and the sub-circuit board 3 are joined to each other with the solder. Since the circuit module 1 is joined with the solder, the joint portion has a high strength, and the reliability of the joint of the circuit module can be improved.

A plurality of lens optical systems 100 and the circuit module 1 were mounted in the lens barrel 400 to produce the optical device 500. Optical performance is sufficiently ensured even after the drop impact testing.

### Example 5

FIGS. 10A to 10C are schematic views illustrating the eighth embodiment of the connection electrodes of the arc-shaped printed wiring board according to the present disclosure. FIG. 10A is a perspective view illustrating the eighth embodiment, FIG. 10B is a plan view illustrating the connection electrodes of the arc-shaped printed wiring board, and FIG. 10C is a sectional view taken along plane XC of FIG. 10A illustrating the eighth embodiment.

FIG. 10B is a schematic view of the connection electrodes of the arc-shaped printed wiring board. The region 70 where the solder resist is formed and the region 71 where the solder resist is not formed exist on the surface layer of the wiring board 21. The size of the region 71 where the solder resist is not formed is as follows: the length is about 14.5 mm; and the width is about 1.2 mm. The position of the center of gravity of the region 71 where the solder resist is not formed and the position of the center of gravity of the region where the wiring board 31 is to be placed are coincident with each other. That is, the solder resist is not formed in length D1 portions of the connection electrode group 41 and 42.

With the other structures set to be similar to example 1, the circuit module 1 was fabricated in which the arc-shaped main circuit board 2 and the sub-circuit board 3 are joined to each other with the solder.

Since solder resist 70 is not formed on the side surfaces of the electrode lands, the solder is aggregated to the side surfaces of the electrode lands. Thus, the width tₛ of the solder 62 becomes greater than the land width W1 in FIG. 10C, and accordingly, the joint strength can be further improved. In this way, the circuit module 1 was fabricated in which the arc-shaped main circuit board 2 and the sub-circuit board 3 are joined to each other with the solder. Since the circuit module 1 is joined with the solder, the joint portion has a high strength, and the reliability of the joint of the circuit module can be improved.

A plurality of lens optical systems 100 and the circuit module 1 were mounted in the lens barrel 400 to produce the optical device 500. Optical performance is sufficiently ensured even after the drop impact testing.

### Example 6

The circuit module 1 illustrated in FIGS. 14A and 14B was manufactured with the method of manufacturing illustrated with reference to FIGS. 5(a) to 5(d) and FIGS. 12A to 12F. The integrated-circuit component 7 and the electronic components 102 such as resistors as the system circuitry are placed on the sub-circuit board 3, and the other electronic components 101 including the electronic components of the driver circuit system are placed on the arc-shaped main circuit board 2. Furthermore, the arc-shaped metal portions M1 and M2 were disposed on the end surface 302 of the sub-circuit board 3. Furthermore, copper chips 1301 were disposed, as the self-support assisting members, at both the ends on both the surfaces of the sub-circuit board 3.

Referring to FIG. 12A, an FR4 four-layer printed wiring board is used as the wiring board 31. The outline size of this board is about 60.0 mm×about 90.0 mm, and the thickness is 0.8 mm. A total of 100 connection electrodes including 50 electrodes as the connection electrode group 51 and 50 electrodes as the connection electrode group 52 are formed on the surface layer of the base board 3000 as follows: the thickness of copper is 0.015 mm; the width W1 is 0.15 mm; the pitch P1 of the adjacent connection electrodes is 0.25 mm; and the length D1 is 0.20 mm. Furthermore, lines to be served as the lines G11 and G12 are formed as follows: the thickness of copper is 0.015 mm; the width W1 is 0.15 mm; and the length D1 is 60.0 mm. Lines to be served as the lines G21 and G22 are formed as follows: the thickness of copper is 0.015 mm; the width W1 is 0.15 mm; and the length D2 is 90.0 mm. Furthermore, through holes are formed as follows: a hole diameter is ΦD 0.25 mm; a land diameter is ΦD 0.5 mm, and holes are plated with copper to a thickness of greater than or equal to 25 m.

Next, referring to FIG. 12B, solder paste 600 including a composition of balance-tin the melting point of which is 220° C., 3-silver, and 3-copper was formed on a subset of the connection electrodes 50, 51, and 52 and the lines to be served as G21 and G22 of the base board 3000 with a screen printing method.

Referring to FIG. 12C, the integrated-circuit component 7 and the electronic components 102 were placed on the solder paste 600 on the connection electrodes 50 with the mounter. Furthermore, parent members (not illustrated) to become the self-support assisting members 1301 were placed, with the mounter, on the solder paste 600 on the lines G21 and G22 and the connection electrode groups 51 and 52 at both the ends of the sub-circuit board 3. At this time, members might be placed on the solder paste on the lines G2 (not illustrated). As the parent members of the self-support assisting members 1301, a copper chip having a size of 2.1 mm×2.1 mm, and a thickness of 1 mm were used.

Referring to FIG. 12D, by using the reflow oven, the solder paste 600 was heated to 250° C., which is the temperature higher than or equal to the melting point of the solder, cooled to a temperature lower than the melting point of the solder, and solidified so as to connect the connection electrodes, the electronic components, the self-support assisting members and the like.

According to the present example, the steps from FIG. 12B to 12D were performed again, and the electronic components 102 and the self-support assisting members 1301 were mounted on both the main surfaces of the sub-circuit board 3.

Next, referring to FIG. 12E, the base board 3000 was cut in the X direction and the Y direction with a dicing machine by using a dicing blade having a thickness of 0.1 mm. The main surfaces 303 and 304, the end surfaces 301 and 302, the arc-shaped metal portions M1 and M2 formed by cutting the through holes, and the self-support assisting members 1301 of the sub-circuit board 3 were formed. The sub-circuit boards 3 having an outline size of 14.0 mm×15.0 mm and a thickness of 0.8 mm were fabricated. The arc-shaped metal portions M1 and M2 are connected to the lines G11, G12, G21, and G22.

Next, referring to FIG. 5(a), the FR4 four-layer printed wiring board is used as the wiring board 21 of the arc-shaped main circuit board 2. The outline size of this board is as follows: the outer diameter is about 54.0 mm; the inner diameter is about 49.0 mm; and the thickness is 0.8 mm. A total of 100 connection electrodes including 50 electrodes as the connection electrode group 41 and 50 electrodes as the connection electrode group 42 are formed on the surface layer of the wiring board as follows: the thickness of copper is 0.015 mm; the width W1 is 0.15 mm; the pitch P1 of the adjacent connection electrodes is 0.25 mm; and the length D1 is 0.20 mm. The precoated solder 61 formed when the electronic components 101 are placed on the connection electrodes 40 and joined to the connection electrodes 40 with the solder 60 is formed on the connection electrode groups 41 and 42. The precoated solder 61 has a composition of balance-tin the melting point of which is 220° C., 3-silver, and 3-copper.

Next, referring to FIG. 5(b), flux (not illustrated) was applied with the dispenser onto the precoated solder 61 on the connection electrode groups 41 and 42. Since the self-support assisting members 1301 are disposed on the sub-circuit board 3 this time, the application of the UV adhesive and the UV radiation which would otherwise have been performed after the application of the UV adhesive were not performed.

Next, referring to FIG. 5(c), the sub-circuit board 3 was placed so as to be astride the connection electrode groups 41 and 42 of the arc-shaped main circuit board 2 at a position corresponding to the connection electrode groups 51 and 52 of the sub-circuit board 3 by performing alignment with the metal portions M1 and M2 of the sub-circuit board 3.

After the placement of the sub-circuit board 3, with the self-support assisting members 1301, toppling of the sub-circuit board 3 or deviation of the placement position does not occur before the following heating step and even in the hot air during the reflow.

Next, referring to FIG. 5(d), with the reflow oven, the precoated solder 61 was heated, heating was performed to a temperature higher than or equal to the melting point of the solder, the precoated solder 61 on the connection electrode groups 41 and 42, the connection electrode groups 51 and 52, and the lines G21 and G22 were melted and integrated, and the integrated precoated solder 61 was cooled to a temperature lower than the melting point of the solder so as to be solidified. When the precoated solder 61 is integrated, and the solder is solidified, the arc-shaped main circuit board 2 and the sub-circuit board 3 are electrically and mechanically connected to each other through the solder 62. Furthermore, also the metal portions M1 and M2 are connected to the internal layer GND line G3 of the main circuit board 2 through the lines G11, G12, G21, and G22, the connection electrode groups 51, 52, 41, and 42, the self-support assisting members 1301, and the solder 62 and 63.

Thus, the circuit module 1 was fabricated in which the arc-shaped main circuit board 2 and the sub-circuit board 3 are joined to each other with the solder. Since the circuit module 1 is joined with the solder, the joint portion has a high strength, and the reliability of the joint of the circuit module can be improved. Furthermore, generation of noise can be reduced.

A plurality of lens optical systems 100 and the circuit module 1 were mounted in the lens barrel 400 to produce the optical device 500. Optical performance is sufficiently ensured even after the drop impact testing.

### OTHER EMBODIMENTS

The above-described embodiments and examples only exemplify some forms applicable to the present disclosure. That is, the present disclosure is not limited to the above-described embodiments and examples and can be modified or varied as appropriate without departing from the gist of the present disclosure.

Although the system circuitry and the driver circuit system exemplify the circuit system placed on the sub-circuit board 3 of the circuit module according to the above-described embodiments, application to PKG and the like such as, for example, a memory IC and a CMOS sensor is possible.

According to the above-described embodiments, the circuit module 1 is applied to the optical device including the lens optical system. However, the circuit module 1 that includes the main circuit board 2 having the end surface 204 extending along an arc and the end surface 203 between the end surface 204 and the center of the arc along which the end surface 204 extends can also be applied to various types of electric devices or mechanical devices in addition to the optical device. Regarding the main circuit board 2 having the end surface 204 extending along the arc, the end surface 204 is set to have an arc shape because of a limitation on an installation area of the circuit module 1. Thus, in the circuit module 1, it is useful to increase the installation area by soldering the sub-circuit board 3 to the main circuit board 2. Although the end surface 203 can also extend along an arc, the end surface 203 does not necessarily extend along an arc. The end surface 203 may extend along a line. That is, the main circuit board 2 may have a semicircular shape or a quarter-circular shape. Alternatively, the main circuit board 2 may have a discoidal shape having a polygonal opening. For example, the circuit module 1 can be disposed in a joint of a robot arm being an example of the mechanical device. In this case, a motor, a reduction gear, or shafts of these, and electrical cable can be disposed inside the end surface 203. The sub-circuit board can also be soldered to an annular or arc-shaped main circuit board of an annular illumination device.

The embodiments having been described can be changed as appropriate without departing from the technical thought. For example, a plurality of the embodiments can be combined with each other. Furthermore, a subset of items of at least one of the embodiments can be deleted or replaced. Furthermore, a new item can be added to at least one of the embodiments.

The content of the disclosure herein includes not only the explicit description herein but also all the items understandable herein and from the attached drawings. The content of the disclosure herein includes complements of individual concepts described herein. That is, when, for example, description indicating to the effect that “A is B” is included herein, this can mean that a case of “A is not B” is also disclosed herein even in a case where description of the case of “A is not B” is omitted. The reason for this is that, when “A is B” is described, this description is made on the assumption that the case of “A is not B” is considered.

According to the present disclosure, the technique that is useful in improving the reliability of the connection of the circuit board in the optical device can be provided.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-189344, filed Nov. 28, 2022, which is hereby incorporated by reference herein in its entirety.

What is claimed is:

1. An optical device comprising:
a lens optical system that includes a plurality of lenses disposed along an optical axis;
a first circuit board that has a first main surface extending along a direction intersecting the optical axis of the lens optical system and has a second main surface on a side of the first circuit board that is opposite from a side that the first main surface is on; and
a second circuit board that has a third main surface extending along a direction intersecting the first main surface and has a fourth main surface on a side of the second circuit board that is opposite from a side that the third main surface is on,
wherein the first circuit board and the second circuit board are soldered to each other.

2. The optical device according to claim 1,
wherein the first circuit board includes a first connection electrode group on the first main surface, and the second circuit board includes a second connection electrode group on the third main surface, and
wherein the first connection electrode group and the second connection electrode group are soldered to each other.

3. The optical device according to claim 2,
wherein the first circuit board includes a third connection electrode group on the first main surface, and the second circuit board includes a fourth connection electrode group on the fourth main surface, and
wherein the third connection electrode group and the fourth connection electrode group are soldered to each other.

4. The optical device according to claim 2, wherein a pitch of two electrodes adjacent to each other included in the second connection electrode group is smaller than a thickness of a wiring board of the first circuit board.

5. The optical device according to claim 2, wherein, in an arrangement direction in which a plurality of electrodes included in the second connection electrode group is arranged, a sum of lengths of the plurality of electrodes is greater than or equal to half a length of the second circuit board in the arrangement direction.

6. The optical device according to claim 2,
wherein at least a first electrode included in one connection electrode group out of the first connection electrode group and the second connection electrode group has a first portion and a second portion closer to another connection electrode group out of the first connection electrode group and the second connection electrode group than the first portion, and
wherein a length of the second portion in a first arrangement direction in which a plurality of electrodes included in the one connection electrode group is arranged is greater than a length of the first portion in the first arrangement direction.

7. The optical device according to claim 2, wherein the second circuit board includes a glass epoxy board, and the third main surface is positioned between the fourth main surface and the optical axis, or the fourth main surface is positioned between the third main surface and the optical axis.

8. The optical device according to claim 2, wherein
at least a first electrode included in one connection electrode group out of the first connection electrode group and the second connection electrode group has a third portion and a fourth portion closer to another connection electrode group out of the first connection electrode group and the second connection electrode group than the third portion, and wherein
a length of the third portion in a first arrangement direction in which a plurality of electrodes included in the one connection electrode group is arranged is greater than a length of the fourth portion in the first arrangement direction.

9. The optical device according to claim 8,
wherein at least a second electrode included in the other connection electrode group has a fifth portion and a sixth portion closer to the one connection electrode group than the fifth portion,
wherein a length of the sixth portion in a second arrangement direction in which a plurality of electrodes included in the other connection electrode group is arranged is greater than a length of the fifth portion in the second arrangement direction, and
wherein the first electrode and the second electrode are soldered to each other.

10. The optical device according to claim 1, wherein, in a direction extending along the optical axis, the second circuit board is disposed on an image side of the lens optical system relative to the first circuit board.

11. The optical device according to claim 1, further comprising a resin member with which the first circuit board and the second circuit board are fixed to each other.

12. The optical device according to claim 1, wherein the second circuit board includes an integrated-circuit component placed on the third main surface.

13. The optical device according to claim 12, wherein a distance between the first main surface and the integrated-circuit component is smaller than half a height of the second circuit board with reference to the first main surface.

14. The optical device according to claim 1, wherein the second circuit board includes a plurality of passive components placed on the third main surface.

15. The optical device according to claim 14, wherein a first angle formed between a longitudinal direction of at least one passive component out of the plurality of passive components and the first main surface is greater than or equal to 60 degrees.

16. The optical device according to claim 15, wherein a second angle formed between the longitudinal direction of the at least one passive component out of the plurality of passive components and the first main surface is smaller than or equal to 30 degrees.

17. The optical device according to claim 1, wherein the first circuit board includes a passive component placed on the first main surface.

18. The optical device according to claim 1, wherein the first circuit board includes an electronic component placed on the second main surface.

19. The optical device according to claim 18, wherein the electronic component is superposed on the second circuit board.

20. The optical device according to claim 1, further comprising a connection mechanism to be connected to a connection mechanism of a camera body.

21. A camera comprising:
the optical device according to claim 1; and
an image capturing device configured to capture an image formed by the optical device.

22. A circuit module comprising:
a first circuit board that has a first end surface extending along an arc, a second end surface between the first end surface and a center of the arc, a first main surface, and a second main surface on a side of the first circuit board that is opposite from a side that the first main surface is on; and
a second circuit board that has a third main surface extending along a direction intersecting the first main surface and has a fourth main surface on a side of the second circuit board that is opposite from a side that the third main surface is on,
wherein the first circuit board and the second circuit board are soldered to each other.

23. The circuit module according to claim 22, wherein the first circuit board does not extend to the center of the arc.

24. The circuit module according to claim 22,
wherein the first circuit board includes a first connection electrode group on the first main surface, the second circuit board includes a second connection electrode group on the third main surface, and the first connection electrode group and the second connection electrode group are soldered to each other, and
wherein the first circuit board includes a third connection electrode group on the first main surface, the second circuit board includes a fourth connection electrode group on the fourth main surface, and the third connection electrode group and the fourth connection electrode group are soldered to each other.

25. A circuit module comprising:
a first circuit board that has a first main surface and a second main surface on a side of the first circuit board that is opposite from a side that the first main surface is on; and
a second circuit board that has a third main surface extending along a direction intersecting the first main surface and has a fourth main surface on a side of the second circuit board that is opposite from a side that the third main surface is on,
wherein the first circuit board and the second circuit board are soldered to each other,
wherein the first circuit board includes a first connection electrode group on the first main surface, the second circuit board includes a second connection electrode group on the third main surface, and the first connection electrode group and the second connection electrode group are soldered to each other,
wherein at least a first electrode included in one connection electrode group out of the first connection electrode group and the second connection electrode group has a first portion and a second portion closer to another connection electrode group out of the first connection electrode group and the second connection electrode group than the first portion, and
wherein a length of the first portion in a first arrangement direction in which a plurality of electrodes included in the one connection electrode group is arranged is different from a length of the second portion in the first arrangement direction.
